(19) United States
(12) Patent Application Publication
(10) Pub. No.: US 2026/0231466 A1
(43) Pub. Date: Aug. 6, 2026

(54) SEMICONDUCTOR DEVICES WITH CHANNEL AND JUNCTION STRUCTURES AND METHODS OF FABRICATION THEREOF

(71) Applicant: TEXAS INSTRUMENTS INCORPORATED, Dallas, TX (US)

(72) Inventors: Daniel Pham, Celina, TX (US); Steven Huynh, Melissa, TX (US); Henry Litzmann Edwards, Garland, TX (US)

(21) Appl. No.: 19/043,226

(22) Filed: Jan. 31, 2025

(51) Int. Cl. H10D 30/65; H10D 30/01; H10D 62/00; H10D 62/10; H10D 64/01; H10D 64/27

(52) U.S. Cl. CPC H10D 30/658; H10D 30/0285; H10D 30/0289; H10D 62/052; H10D 62/111; H10D 62/115; H10D 64/027; H10D 64/513; H10D 64/516

(57) ABSTRACT

Semiconductor devices and fabrication methods thereof are described. For example, a semiconductor device includes a semiconductor layer including fins disposed over a planar portion, a source and a drain drift region disposed in the semiconductor layer, a drain region disposed in the drain drift region. The planar portion and the fins of the semiconductor layer extend from the source region through the drain drift region to the drain region. The semiconductor device also includes a first epitaxial layer disposed over a portion of the fins of the semiconductor layer in the drain drift region, a second epitaxial layer disposed over the first epitaxial layer, the drain drift region having a first doping type and the second epitaxial layer having a second doping type, a gate electrode, and a field relief insulating layer disposed between a portion of the gate electrode and a portion of the second epitaxial layer.

### TECHNICAL FIELD

The present disclosure relates to the field of semiconductor transistors, and more particularly, but not exclusively, to laterally diffused metal oxide semiconductor (LDMOS) transistors.

### BACKGROUND

Semiconductor devices, such as silicon devices, have a wide range of applications. For example, field effect transistors (FETs) and laterally diffused metal oxide semiconductor (LDMOS) devices are used in many applications. While current methods of manufacture for semiconductor devices have been sufficient in past uses, issues arise as the size of the semiconductor devices continues to shrink.

### SUMMARY

The present disclosure describes semiconductor devices with junctions between drift regions and doped layers proximate drain regions, and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer including a planar portion and two or more fins over the planar portion, a source region disposed in the semiconductor layer, a drain drift region disposed in the semiconductor layer, and a drain region disposed in the drain drift region, the planar portion and the two or more fins of the semiconductor layer extending from the source region through the drain drift region to the drain region. The semiconductor device also includes a first epitaxial layer disposed over a portion of the two or more fins of the semiconductor layer in the drain drift region, a second epitaxial layer disposed over the first epitaxial layer, the drain drift region having a first doping type and the second epitaxial layer having a second doping type, a gate electrode, and a field relief insulating layer disposed between a portion of the gate electrode and a portion of the second epitaxial layer.

In some other examples, a method of fabricating a semiconductor device includes forming two or more fins in at least a portion of a semiconductor layer, forming a source region in the semiconductor layer, forming a drain drift region in the semiconductor layer, and forming a drain region in the drain drift region, the two or more fins of the semiconductor layer extending from the source region through the drain drift region to the drain region. The method also comprises forming a first epitaxial layer over a portion of the two or more fins of the semiconductor layer in the drain drift region and forming a second epitaxial layer over the first epitaxial layer, the drain drift region having a first doping type and the second epitaxial layer having a second doping type. The method further includes forming a gate electrode and forming a field relief insulating layer disposed between a portion of the gate electrode and a portion of the second epitaxial layer.

In some other examples, a method of fabricating a semiconductor device includes forming two or more fins in at least a portion of a semiconductor layer, forming a source region in the semiconductor layer, forming a drain drift region in the semiconductor layer, and forming a drain region in the drain drift region, the two or more fins of the semiconductor layer extending from the source region through the drain drift region to the drain region. The method also includes forming a gate electrode having a first portion and a second portion, forming a field relief insulating layer disposed between the first and second portions of the gate electrode, and forming a first epitaxial layer over first and second portions of the two or more fins of the semiconductor layer in the drain drift region, the first portion of the two or more fins of the semiconductor layer below the field relief insulating layer having a first height and the second portion of the two or more fins of the semiconductor layer extending from the field relief insulating layer to the drain region having a second height. The method further includes forming a second epitaxial layer over the first epitaxial layer, the drain drift region having a first doping type and the second epitaxial layer having a second doping type.

### BRIEF DESCRIPTION OF THE DRAWINGS

FIGS. 1A-1C are cross-sectional views of a semiconductor device having a junction between a drift region and a doped layer proximate a drain region in accordance with an example of the present disclosure;

FIGS. 2A-2G are cross-sectional views a method of fabricating a semiconductor device with a buried epitaxial layer in an area where a transistor device will be formed in accordance with an example of the present disclosure;

FIGS. 3A-3T are cross-sectional views of a method of fabricating a semiconductor device having a junction between a drift region and a doped layer proximate a drain region in accordance with an example of the present disclosure;

FIGS. 4A-4D are cross-sectional views of a method of fabricating a semiconductor device having an extended junction between a drift region and a doped layer proximate a drain region in accordance with an example of the present disclosure;

FIGS. 5A-5E are cross-sectional views of a semiconductor device having a junction with first and second sections between a drift region and a doped layer proximate a drain region in accordance with an example of the present disclosure; and

FIGS. 6A-6V are cross-sectional views of a method of fabricating a semiconductor device having a junction with first and second sections between a drift region and a doped layer proximate a drain region in accordance with an example of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to.” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

“Dielectric constant” as used herein with respect to a material refers to the ratio of the real part of the dielectric permittivity of that material to ε₀, the dielectric permittivity of free space. The dielectric constant may be referred to by the symbol k. A “low-k” material is defined as having a dielectric constant less than that of silicon dioxide, e.g., ≤3.5, and a “high-k” dielectric material is defined as having a dielectric constant greater than that of silicon dioxide, e.g., ≥4.

Current laterally diffused metal-oxide-semiconductor (LDMOS) field-effect transistors (FETs) may experience short channel effects as they are scaled down. As the channel region of the LDMOS transistor is scaled down, the leakage current through the channel during use tends to increase. Other short channel effects may include mobility degradation, drain punch-through, and/or threshold voltage roll-off, among others. These may be counteracted by increasing the channel doping concentration. However, a higher dopant concentration in the channel region tends to result in reduced channel mobility.

Various disclosed structures and methods of the present disclosure may be beneficially applied to electronic devices such as LDMOS transistors to improve reliability by reducing such effects, and to allow for further scaling. In some examples, this is achieved through the introduction of a buried isolation area under the device channel. The buried isolation area, also referred to as a buried isolation layer, creates a thin silicon channel thickness (t_{Si}) which may be approximately 10 nanometers for a fully depleted (FD) device or up to approximately 200 nm for a partially depleted (PD) device. The buried isolation area can be extended laterally (L_{channel-iso}) to provide better gate control without reducing the on-state resistance (R_{ds}). The buried isolation area can be extended deep into the substrate to provide an isolation wall between the source and drain (Dᵢₛₒ), where the depth depends on the voltage applied at the drain side. The channel of the LDMOS devices may include a thin nanosheet layer and one or more fins formed above the thin nanosheet layer. The use of fins for the channel increases the channel surface area and volume, allowing for further device scaling. A thicker nanosheet channel and fins provide stability during channel under-etch processing described in further detail below. The fins extend through the drain drift region toward the drain, enabling formation of a “super junction” (sometimes stylized as “superjunction”) at the drain side with n-type and p-type pillars for uniform electric field distribution. In some examples, the super junction has two sections. A first section of the super junction may be formed under a field relief dielectric layer, which is shallower than a second section of the super junction at the drain area. The super junction under the field relief dielectric layer leads to the channel (e.g., the fins and horizontal nanosheet layer channel). A lateral p-n super junction may be formed as a silicon on insulator (SOI) or silicon on sapphire (SOS), or a surface low on-resistance path lateral double-diffusion metal-oxide-semiconductor field-effect transistors (SLOP-LDMOS). The second section of the super junction at the drain area is formed deep into the substrate (e.g., deeper than the drain drift region, and potentially as deep as an electrical isolation layer (e.g., a buried layer) that is formed in the substrate. While such examples may be expected to provide various improvements, such as increased reliability or reduced device size, no particular result is a requirement of the present disclosure unless explicitly recited in a particular claim.

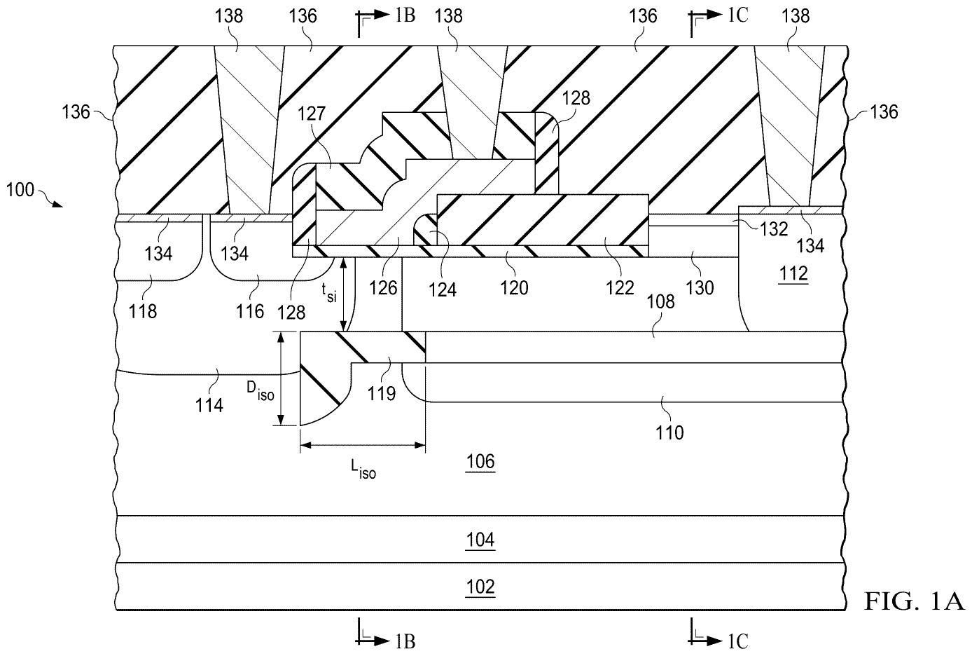

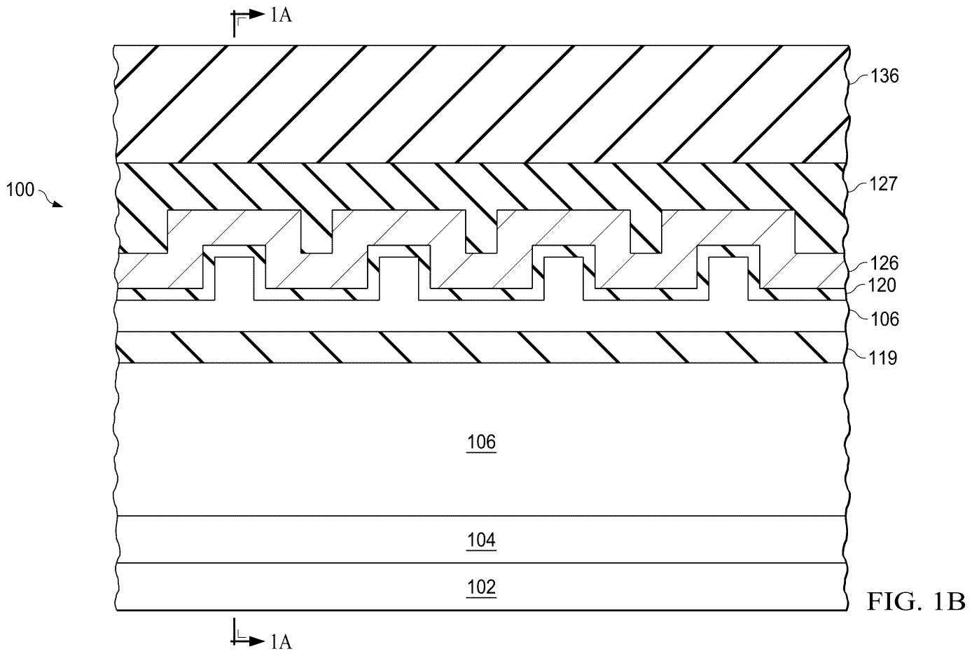

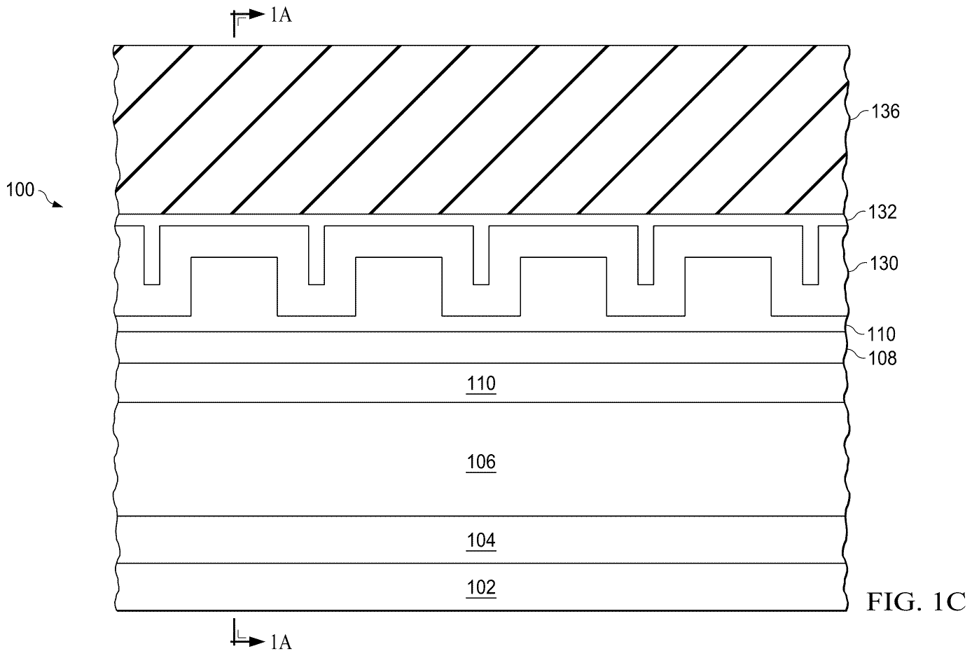

Referring now to FIGS. 1A-1C, an LDMOS transistor 100 is shown in various views. FIG. 1A shows a sectional view along a length direction, (“L-direction”) parallel to a direction from a source to a drain, and FIGS. 1B and 1C show two different views along a width direction (“W-direction”) orthogonal to the L-direction. FIG. 1B shows a sectional view through a channel of the transistor 100, and FIG. 1C shows a sectional view through a drain drift region. These views collectively include a substrate 102, a buried layer 104, a first epitaxial layer 106 of a first semiconductor material, a second epitaxial layer 108 of a second semiconductor material, a drain drift region 110, a drain region 112, a well region 114 such as a D-well, a source region 116, a body (or back-gate) contact region 118, a buried isolation layer 119, a gate dielectric layer 120, a field relief dielectric layer 122, a dielectric spacer 124, a gate electrode 126, a gate hard mask 127, a gate spacer 128, a a first super junction epitaxial layer 130, a second super junction epitaxial layer 132, silicide layers 134, and interlayer dielectric (ILD) layer 136, and contacts 138. The substrate 102, the epitaxial layer 106, the body contact region 118 and the epitaxial layer 132 are a first conductivity type (e.g., p-type), while the buried layer 104, the drain drift region 110, the drain region 112, and the source region 116 are a second conductivity type (e.g., n-type). The epitaxial layer 130 may be undoped, or may be lightly doped (e.g., with a dopant concentration less than that of the drain drift region 110 and the epitaxial layer 132). The drain drift region 110, the epitaxial layer 130 and the epitaxial layer 132 provide a super junction proximate the drain region 112. An unreferenced portion of the gate electrode 126 over the field relief dielectric layer 122 may be regarded as a field plate.

The LDMOS transistor 100 is formed by providing the substrate 102 and forming the buried layer 104 over the substrate 102 and forming the epitaxial layer 106 over the buried layer 104. Optionally, the substrate 102 is p-type silicon, but may also be n-type silicon or SOI. The epitaxial layer 106 has the first conductivity type (e.g., p-type), while the buried layer 104 has the second conductivity type (e.g., n-type, and thus referred to without limitation as an n-type buried layer or NBL). The substrate 102, the buried layer 104 and the epitaxial layer 106 may be formed of silicon, and may also include other semiconducting material.

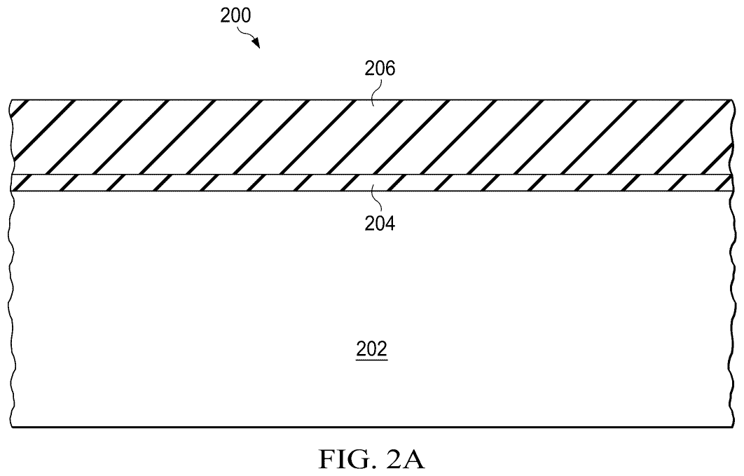

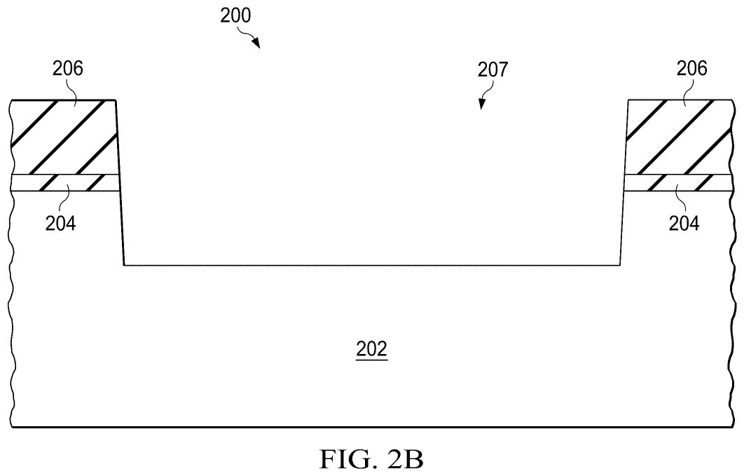

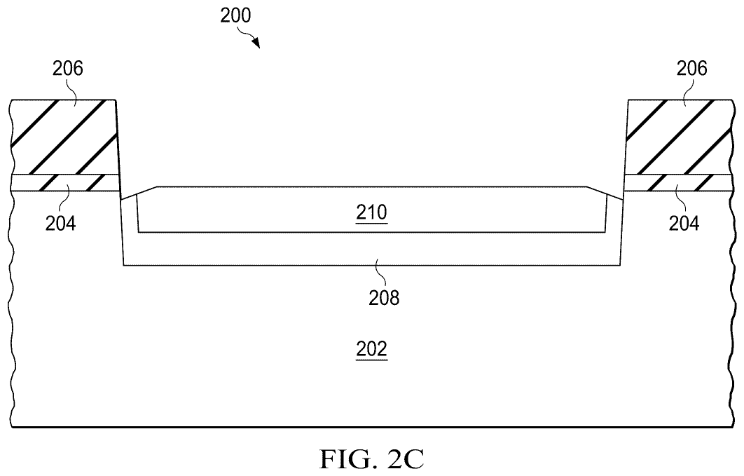

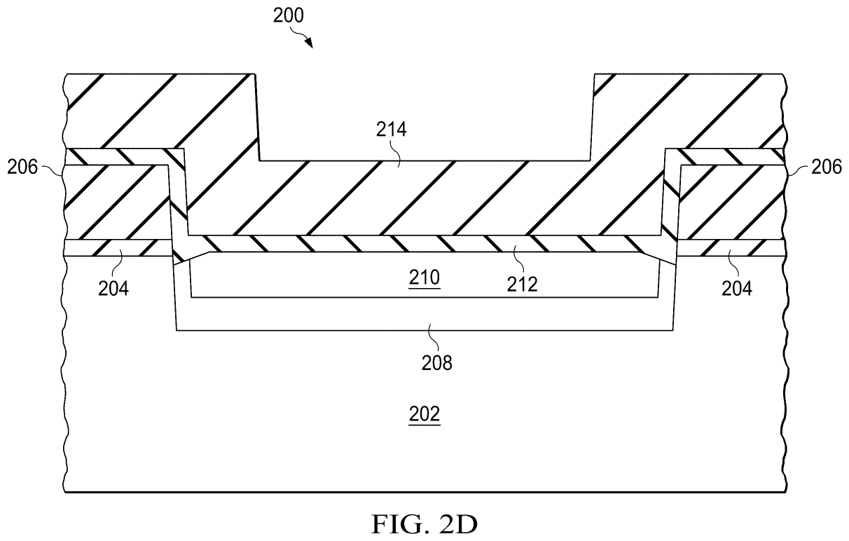

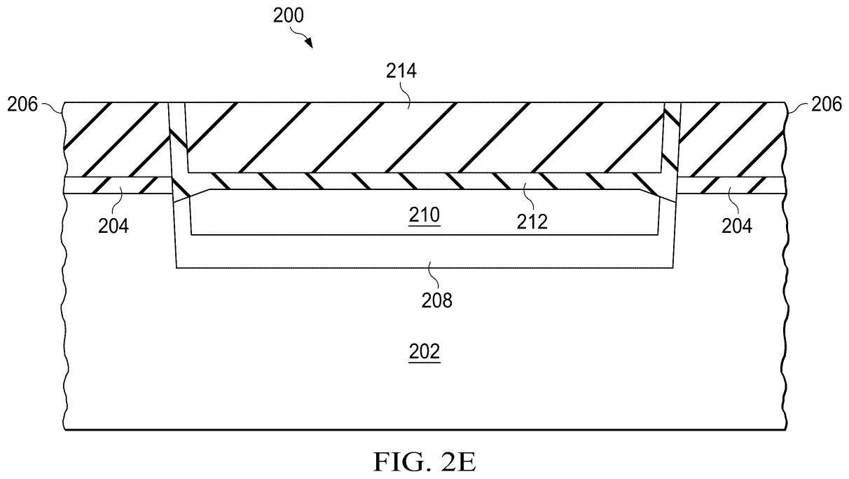

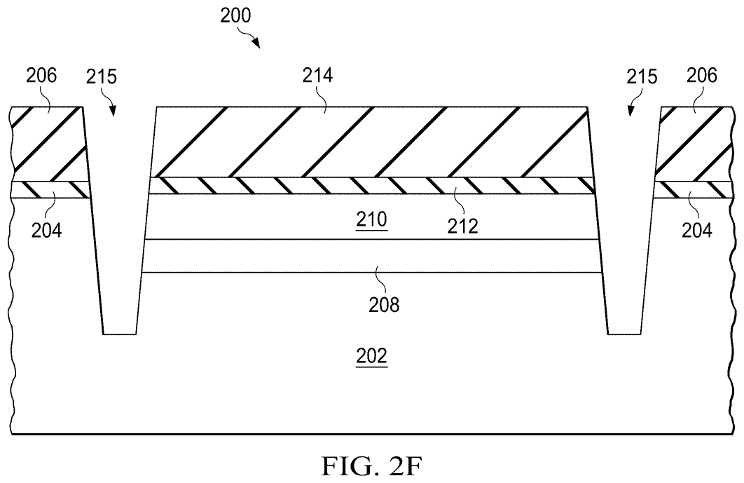

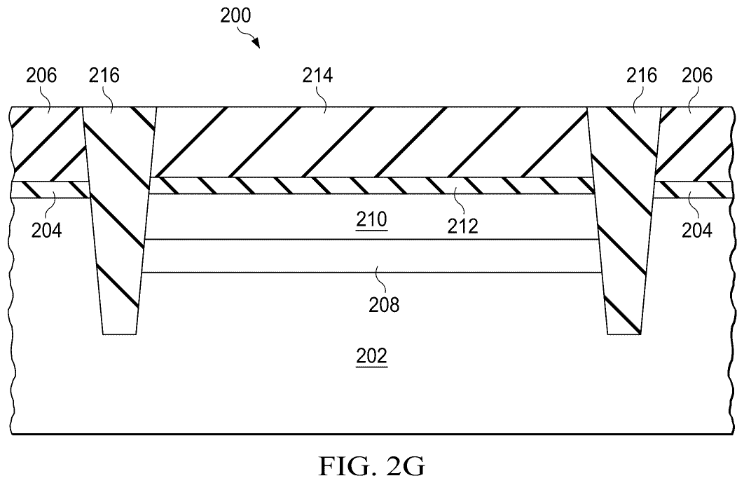

The epitaxial layers 106 and 108 may be referred to collectively as a “heterogenous epitaxial layer”. The epitaxial layer 108 may be formed by patterning an opening in the epitaxial layer 106, followed by deposition of a material for the epitaxial layer 108, followed by growth of another epitaxial layer having similar characteristics (e.g. material and doping) as the epitaxial layer 106 over the epitaxial layer 108. A detailed process flow for forming the epitaxial layer 108 will be described in further detail below with respect to FIGS. 2A-2G. The epitaxial layer 108 is formed of a material which may later be etched selective to that of the epitaxial layer 106. In one example in which the epitaxial layer 106 is formed of silicon, the epitaxial layer 108 may be formed of silicon germanium (SiGe) which may provide such selectivity. The drain drift region 110 is heterogenous in that it includes a lower portion and an upper portion that are doped regions of the epitaxial layer 106, and a middle portion that is a doped portion of the epitaxial layer 108. Unless otherwise stated, reference to the drain drift region 110 implies these three portions.

The drain drift region 110, the drain region 112, the well region 114, the source region 116 and the body contact region 118 may each be formed using one or more ion implant processes (possibly with different energies) followed by optional anneal or thermal drive-in processes, with the use of suitable ion implant masks to form these regions in the locations shown in FIGS. 1A-1C. The drain drift region 110, the drain region 112 and the source region 116 may be the second conductivity type (e.g., n-type) while the well region 114 and the body contact region 118 may be the first conductivity type (e.g., p-type).

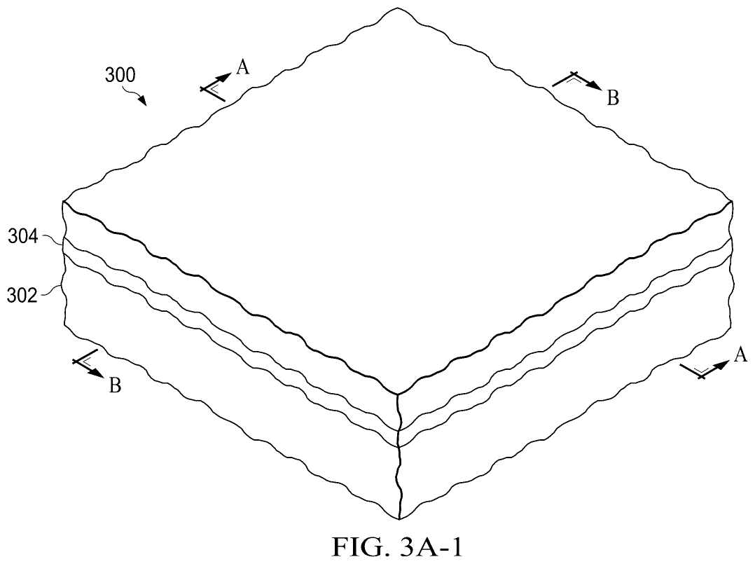

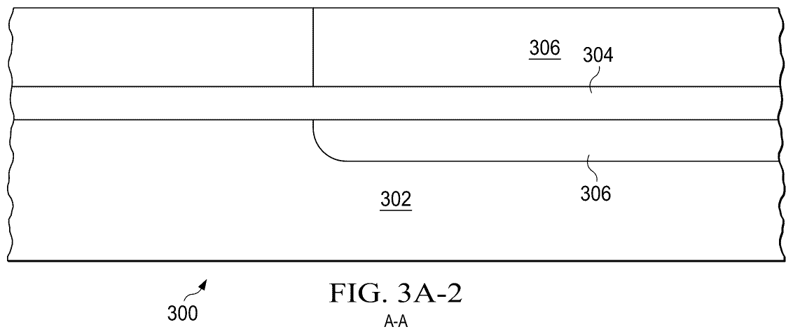

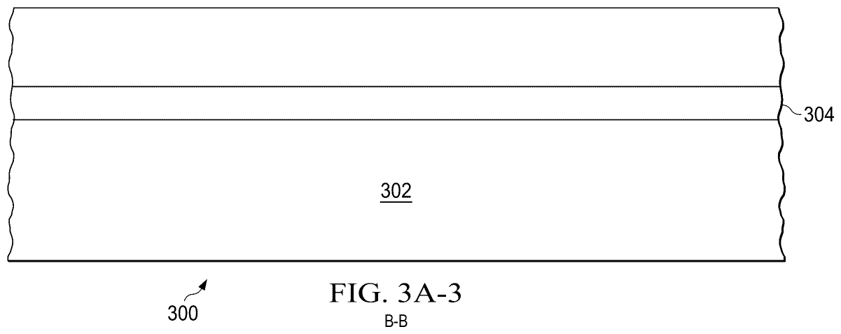

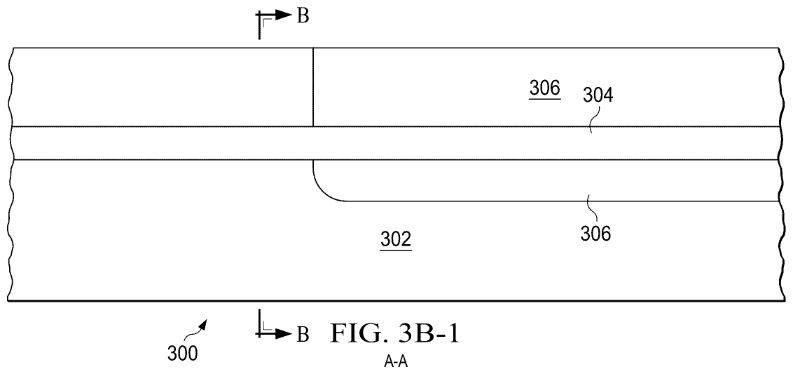

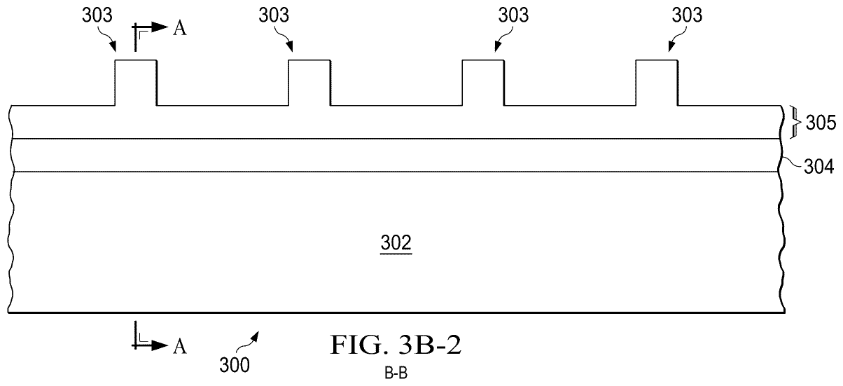

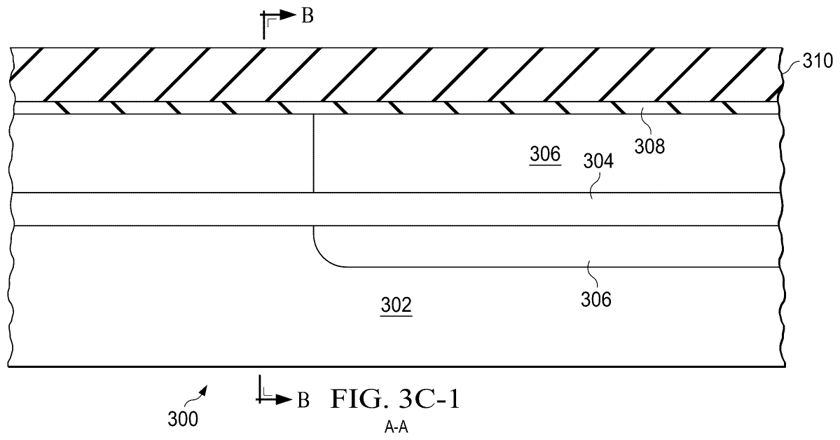

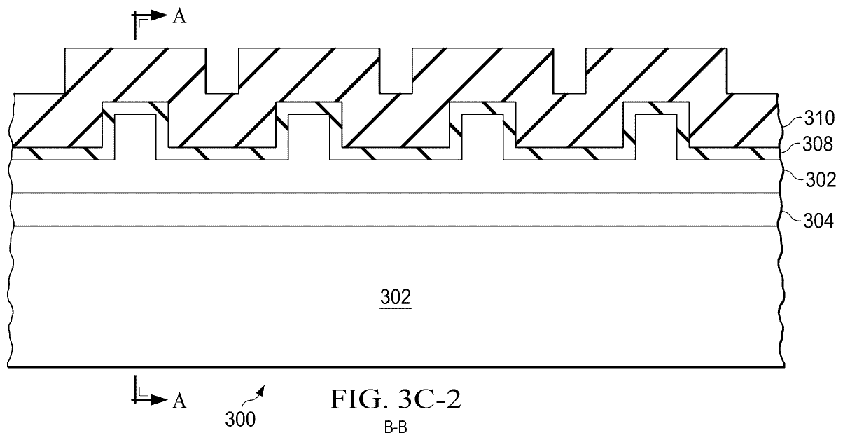

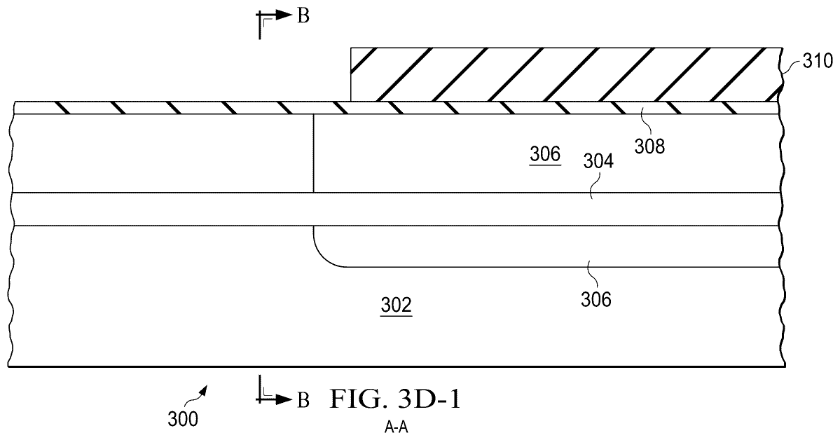

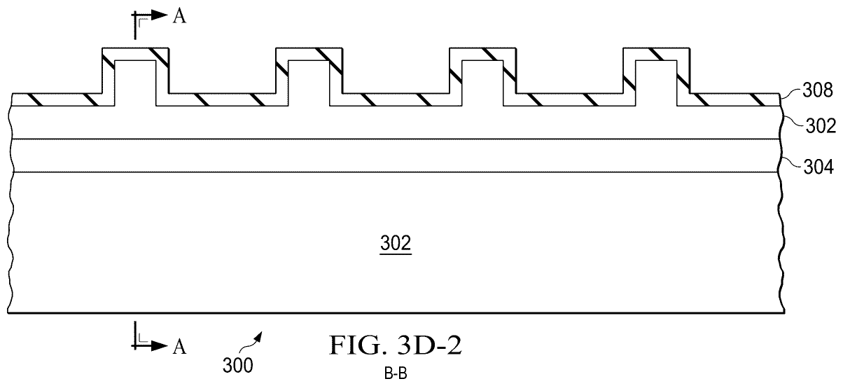

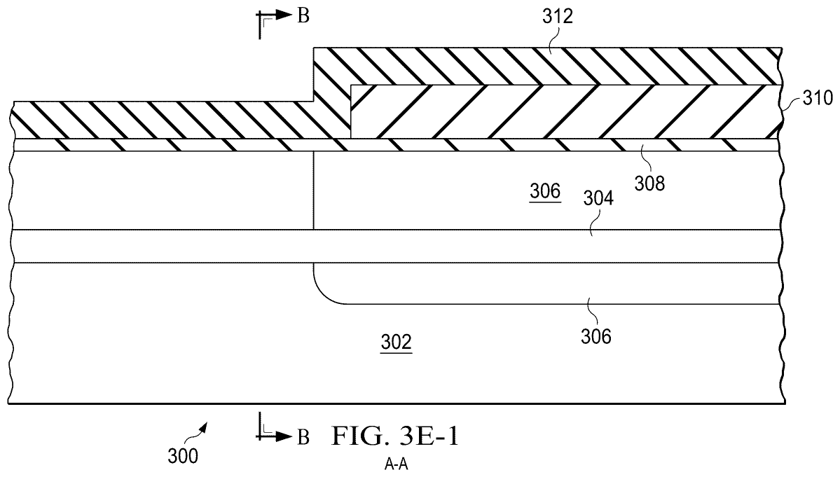

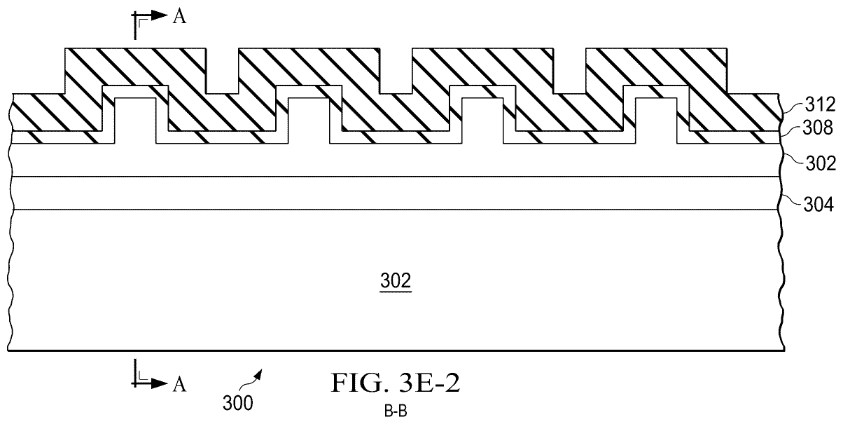

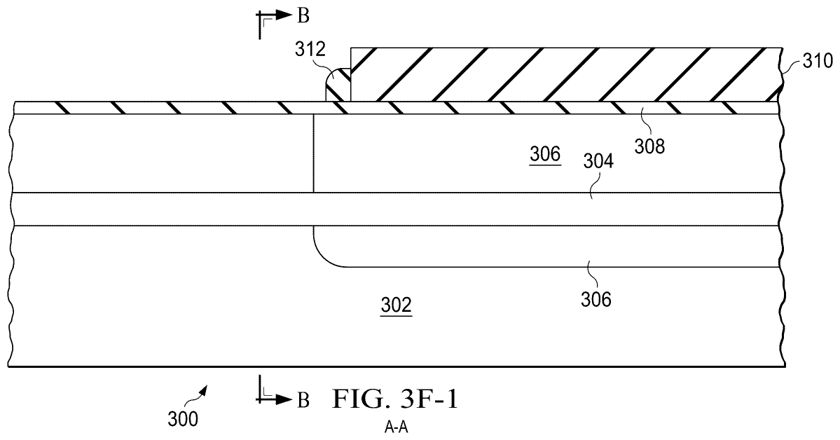

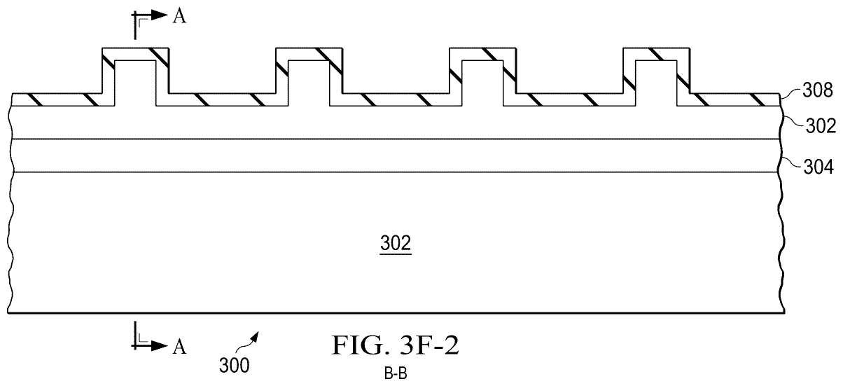

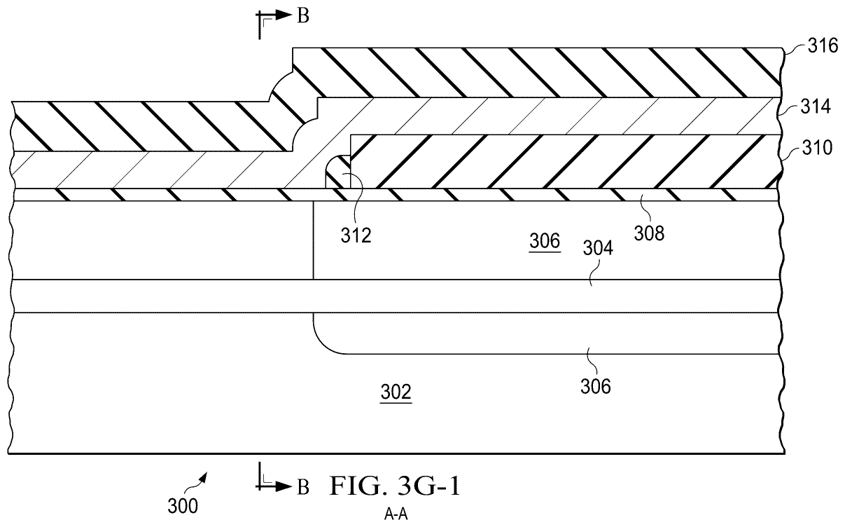

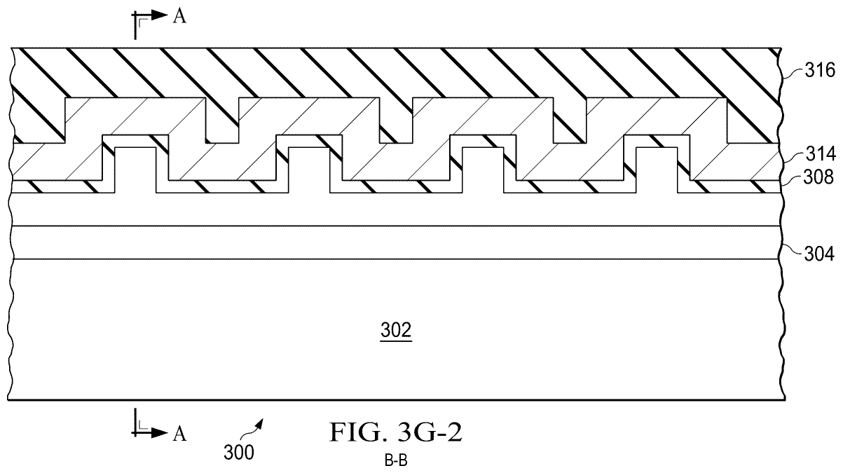

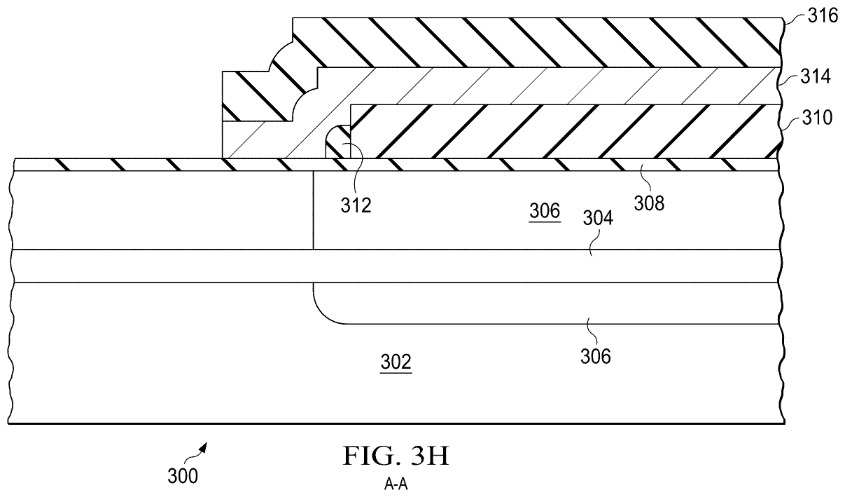

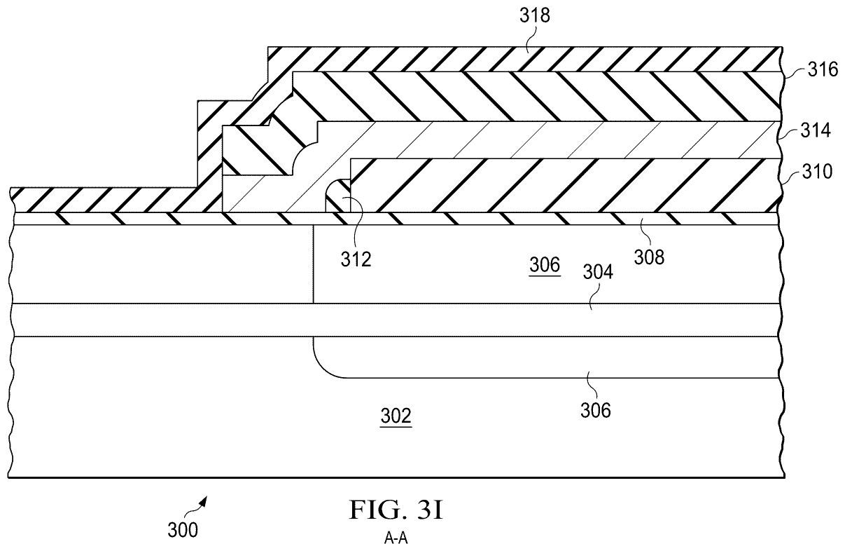

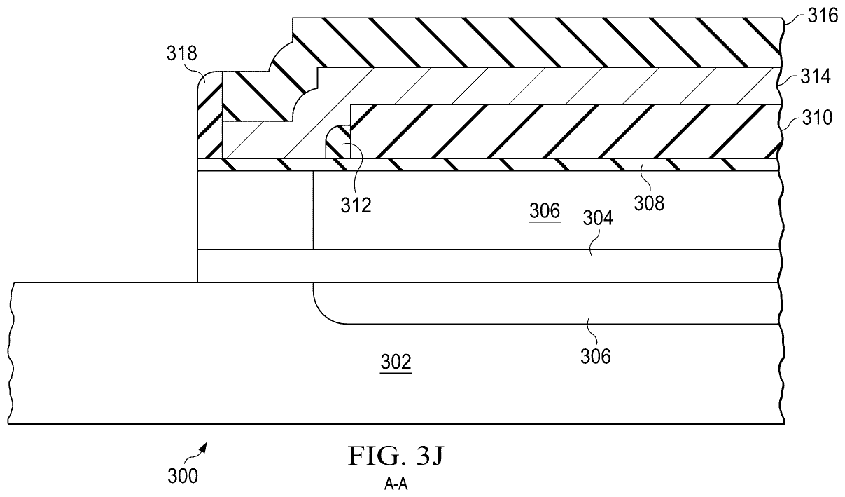

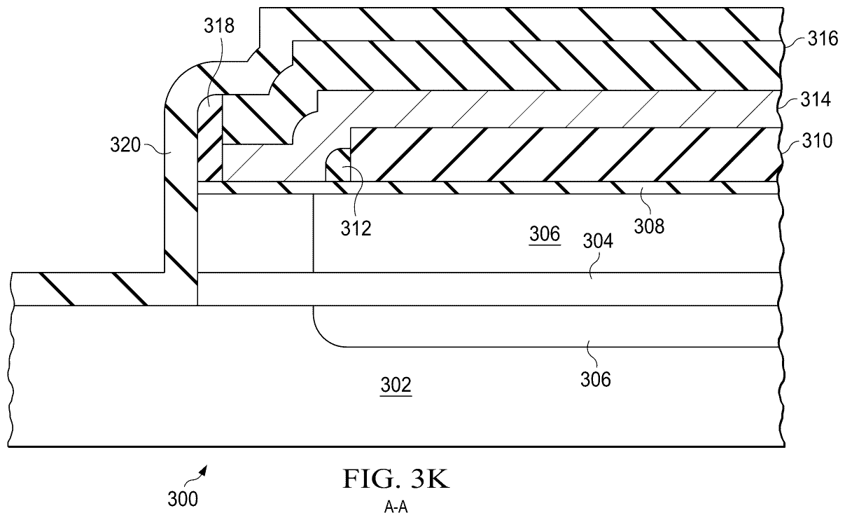

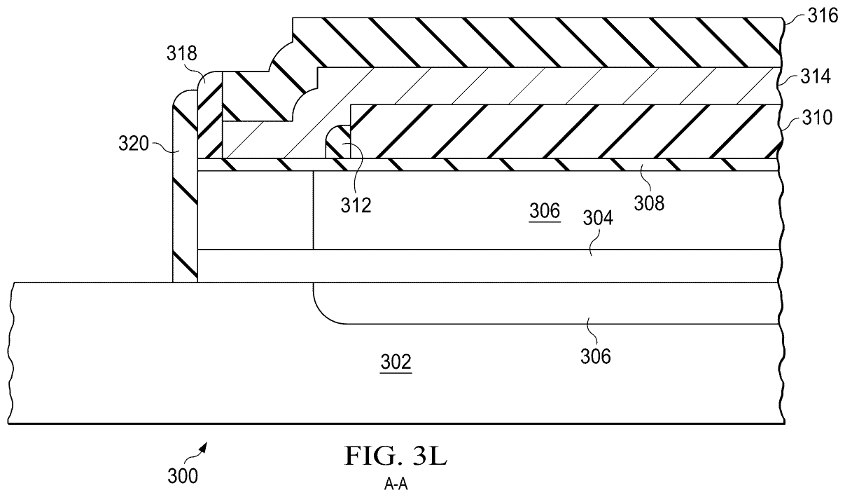

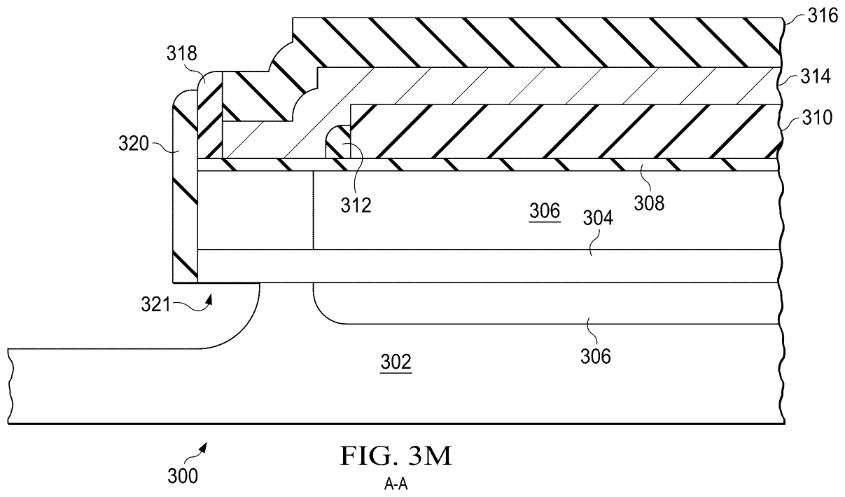

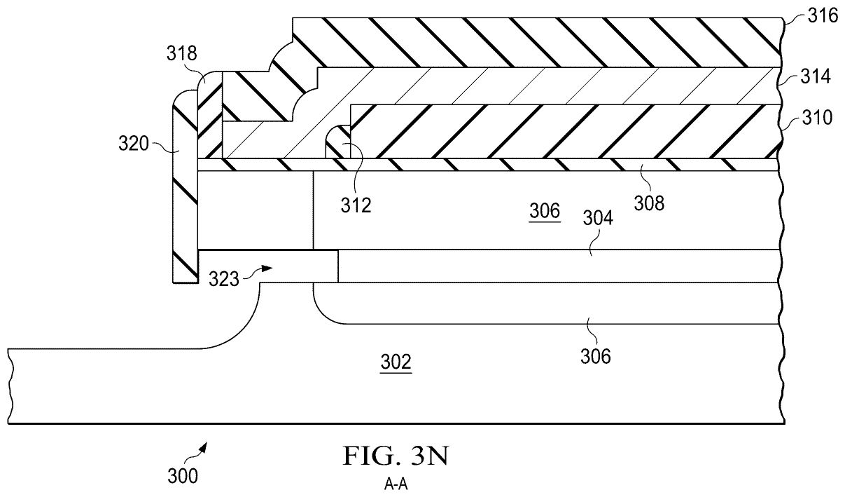

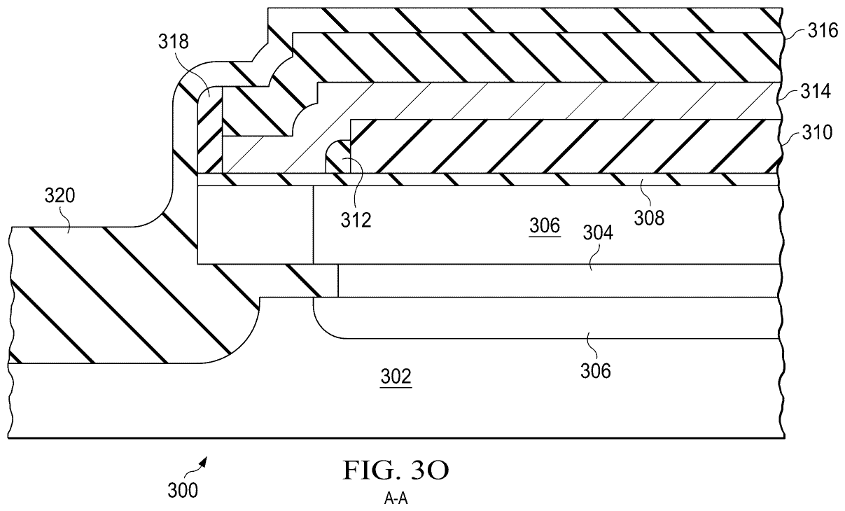

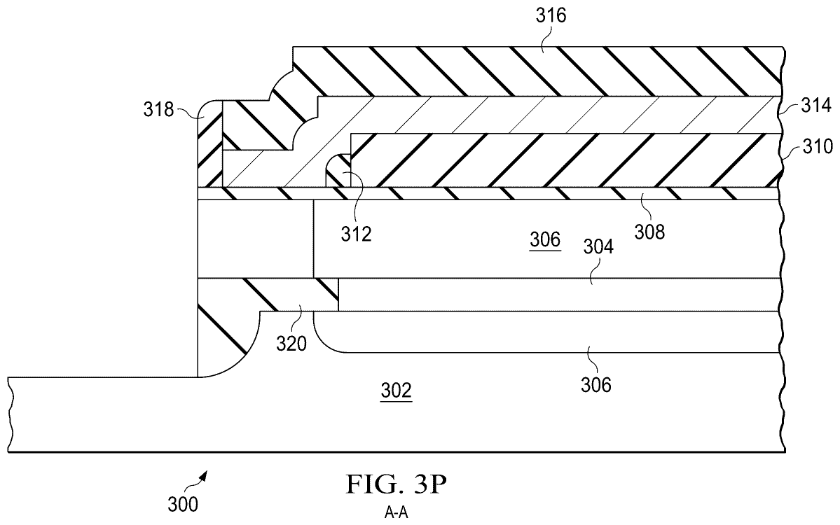

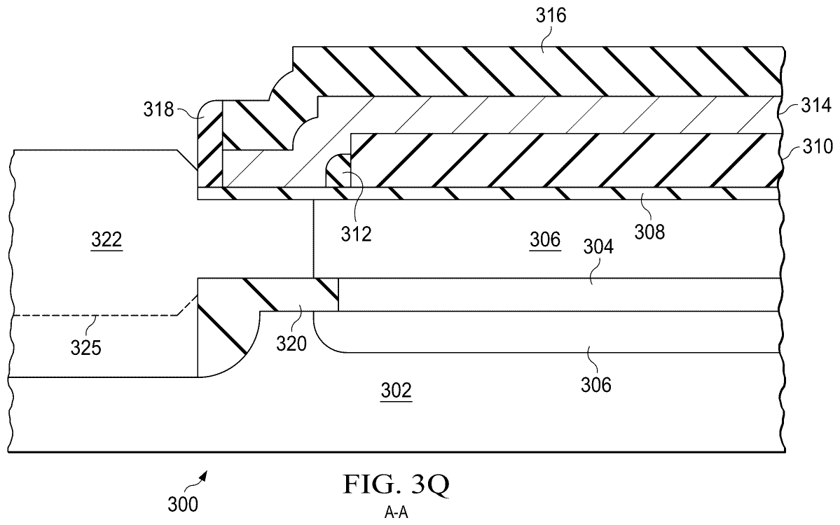

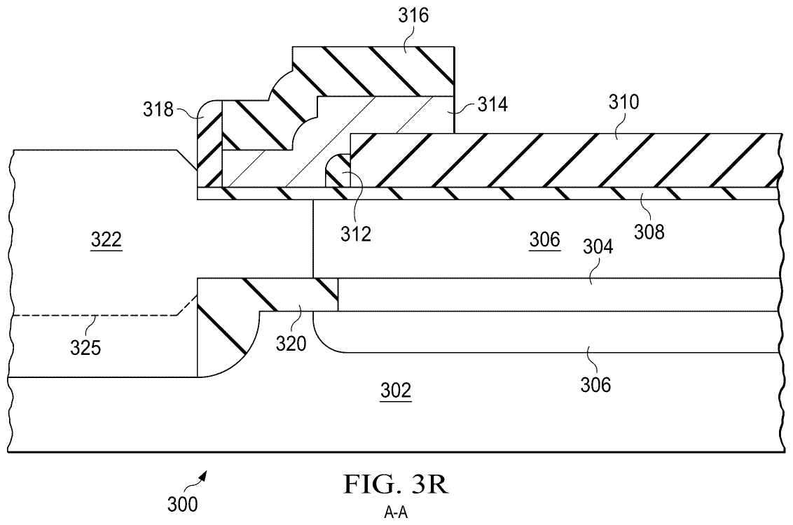

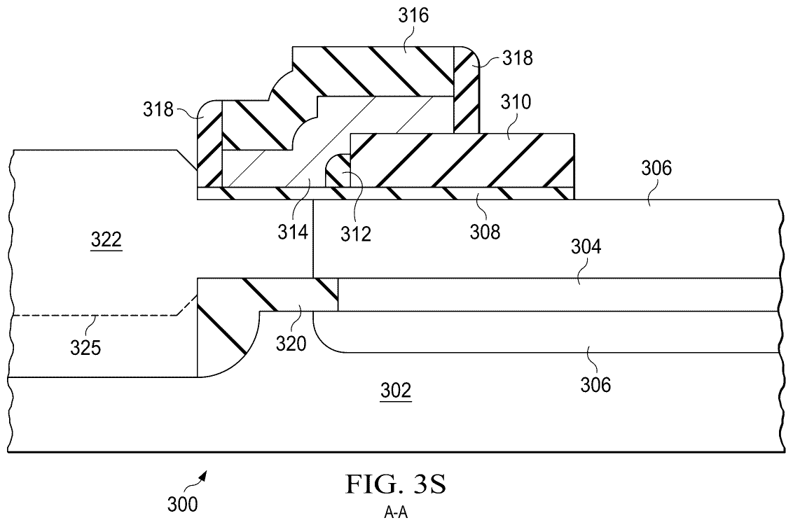

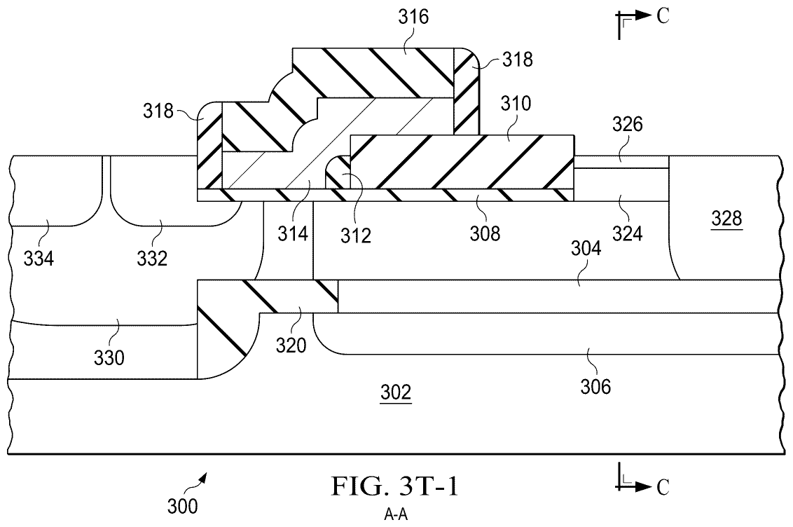

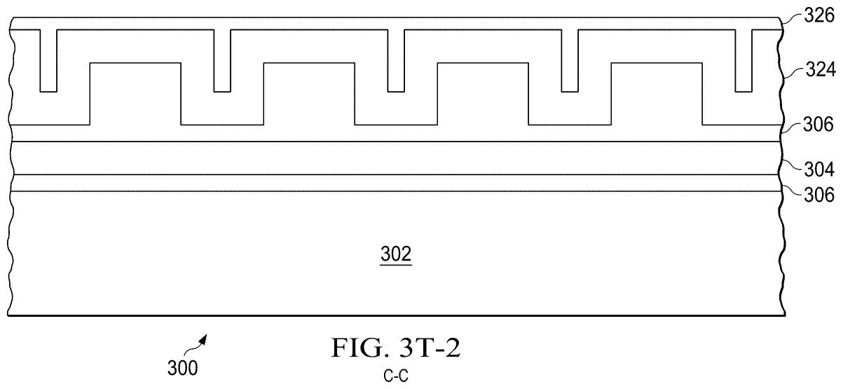

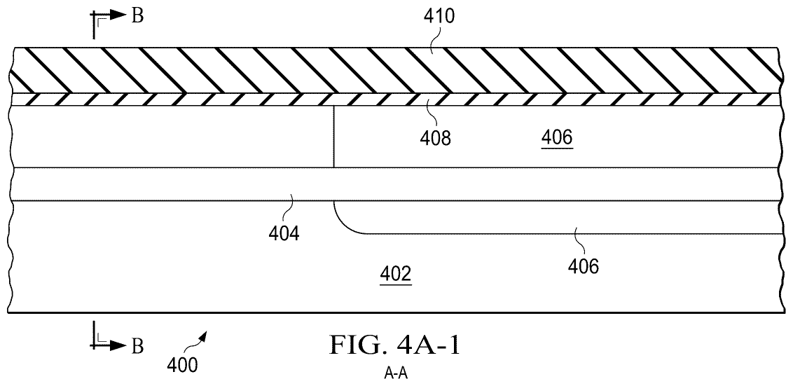

Following formation of the drain drift region 110, a set of fins may be formed in the epitaxial layer 106 (and the drain drift region 110 formed therein) which extend laterally across the structure in the L-direction. The gate dielectric layer 120 is then formed over the fins, followed by formation of the field relief dielectric layer 122. The dielectric spacer 124 is then formed, followed by the gate electrode 126 and the gate hard mask 127. While shown as planar, the gate hard mask 127 may include topography related to the topography of the underlying gate electrode 126. The source area of the epitaxial layer 106 is then opened, followed by formation of the gate spacer 128 on the source side, followed by etching through the epitaxial layer 106 and the epitaxial layer 108. An oxide spacer is then formed, followed by selective etching of the epitaxial layer 106 (e.g., which extends laterally underneath a portion of the epitaxial layer 108). A portion of the epitaxial layer 108 (extending to and possibly partially into the drain drift region 110) is then etched selective to the epitaxial layer 106, followed by deposition of an oxide and an anisotropic etch which forms the buried isolation layer 119. The epitaxial layer 106 is then regrown, followed by gate patterning and etching, and formation of the gate spacer 128 on the drain side. The field relief dielectric layer 122 is then etched, followed by formation of the super junction proximate the drain region 112 including formation of the epitaxial layers 130 and 132. Additional details regarding such processing will be described in further detail below with respect to FIGS. 3A-3T.

The silicide layers 134 are formed over the drain region 112, the source region 116 and the body contact region 118 (e.g., exposed silicon regions), followed by deposition of the ILD layer 136 and formation of the contacts 138. The silicide layers 134, which may be referred to as metal silicide layers, may be formed by deposition of a layer of a metal such as titanium or nickel, which is then heated to form a metal silicide in areas where the metal contacts underlying silicon. After the formation of the silicide, the unreacted metal is removed via a wet etch process leaving the silicide layers 134 in the exposed silicon and polysilicon regions. The ILD layer 136 may be an oxide deposited using CVD, and may be doped with phosphorus or phosphorus and boron, where the dopants serve as a getter for mobile ions. The contacts 138 are formed using a pattern and etch process to form contact holes to the underlying layers, the contact holes generally being filled with a metal such as tungsten.

FIG. 1A shows a lateral or L-direction cross-sectional view of the LDMOS transistor 100, while FIGS. 1B and 1C show width or W-direction cross-sectional views of the LDMOS transistor 100. FIG. 1B shows a cross-sectional view along the channel region of the LDMOS transistor 100, illustrating the channel composed of a planar or nanosheet portion and multiple fins formed over the planar or nanosheet portion, with the buried isolation layer 119 below the channel region. FIG. 1C shows a cross-sectional view along the super junction proximate the drain region 112 of the LDMOS transistor 100. As shown in FIG. 1A, the buried isolation layer 119 has a lateral length L_{channel-iso}, and a depth Dᵢₛₒ. The channel region, which is in the area between the well region 114, the drain drift region 110, the buried isolation layer 119 and the gate dielectric layer 120, has a thickness t_{Si} (e.g., measured between a top surface of the buried isolation layer 119 and a top of the fins).

Referring now to FIGS. 2A-2G, a method of fabricating a semiconductor device is shown. FIGS. 2A-2G show respective cross-sectional views of a structure, illustrating opening of an area where an LDMOS device is to be formed.

FIG. 2A shows a semiconductor structure 200 including an epitaxial layer 202 (e.g., an example of the epitaxial layer 106 in the LDMOS transistor 100 of FIGS. 1A-1C), a padding layer 204, and a hard mask layer 206. The padding layer 204 is formed of an oxide material (e.g., silicon monoxide, silicon dioxide, etc.) or another suitable material that is blanket deposited over the epitaxial layer 202 (e.g., using a chemical vapor deposition (CVD) process) or thermally grown (e.g., using an oxidation process). The padding layer 204 may have a thickness in the range of, for example, 50 -150 angstroms (Å). The hard mask layer 206 is formed of a nitride material (e.g., silicon nitride, silicon oxynitride, etc.), with a thickness corresponding generally to a desired depth of a sacrificial layer that is to be buried in the epitaxial layer 202, though the thickness may be greater or smaller depending on the transfer etch processing that is utilized (e.g., a plasma etch process selectivity).

FIG. 2B shows the semiconductor structure 200 of FIG. 2A following patterning and etching an opening 207 in the hard mask layer 206, the padding layer 204 and the epitaxial layer 202. The opening 207 may be formed by patterning a mask layer (also referred to as an etch mask), followed by a plasma etch process which removes the hard mask layer 206, the padding layer 204 and a portion of the epitaxial layer 202. The mask layer or etch mask, in some examples, includes a photoresist layer formed by a photolithography process. In other examples, the mask layer or etch mask may also or alternatively include a hard mask material such as amorphous carbon, an anti-reflection layer such as an organic bottom anti-reflection coat (BARC), etc. Unless otherwise noted, other mask layers or etch masks described herein may use similar materials.

FIG. 2C shows the semiconductor structure 200 of FIG. 2B following growth of epitaxial layers 208 and 210 in the opening 207. The epitaxial layer 208 (e.g., an example of the epitaxial layer 108 in the LDMOS transistor 100 of FIGS. 1A-1C) may be formed of silicon germanium, while the epitaxial layer 210 is formed of the same material as the epitaxial layer 202 (e.g., silicon). In some examples, the silicon germanium of the epitaxial layer 208 is formed with compressive strain, as relaxed silicon germanium may result in mismatch dislocation defects relative to the underlying epitaxial layer 202 and the epitaxial layer 210 formed over the epitaxial layer 208. The silicon germanium of the epitaxial layer 208 may have a germanium concentration of about 10-40%, and the epitaxial layer 208 may have a thickness of about 50 to 500 nm. The epitaxial layer 210 may have a thickness in the range of about 100 to 1000 nm.

FIG. 2D shows the semiconductor structure 200 of FIG. 2C following deposition of an oxide layer 212 and a nitride layer 214. The oxide layer 212 and the nitride layer 214 may be blanket deposited over the structure, and have thicknesses which are similar to those of the padding layer 204 and the hard mask layer 206. The oxide layer 212 and the nitride layer 214 may be formed of similar materials and with similar processing as that described above with respect to formation of the padding layer 204 and the hard mask layer 206.

FIG. 2E shows the semiconductor structure 200 of FIG. 2D following planarization, using chemical mechanical planarization (CMP) or other suitable processing, such that a top surface of the nitride layer 214 is coplanar with a top surface of the hard mask layer 206.

FIG. 2F shows the semiconductor structure 200 of FIG. 2E following patterning of a mask layer over the structure, and etching portions of the nitride layer 214, the oxide layer 212, the hard mask layer 206, the padding layer 204 and the underlying epitaxial layer 202 to form trenches 215. The trenches 215 define boundaries of where an LDMOS device will be formed.

FIG. 2G shows the semiconductor structure 200 of FIG. 2F following formation of shallow trench isolation (STI) regions 216 in the trenches 215. The STI regions 216 may be formed of an insulating or dielectric material. In some examples, the STI regions 216 (also referred to as dielectric isolation structures) include a dielectric liner and a bulk dielectric material. The dielectric liner and the bulk dielectric material may have different material compositions. In some examples, the STI regions 216 are formed by depositing the insulating or dielectric material followed by a planarization process (e.g., CMP) such that the top surfaces of the STI regions 216 are coplanar with the top surface of the hard mask layer 206.

Referring now to FIGS. 3A-3T, a method of fabricating an LDMOS device with a buried isolation layer (e.g., buried isolation layer 119) and a super junction proximate a drain region is shown. The method shown in FIGS. 3A-3T may start with the structure shown in FIG. 2G, although only an area of the structure of FIG. 2G (with the nitride layer 214, the oxide layer 212, the hard mask layer 206 and the padding layer 204 removed) between the STI regions 216 is shown for clarity of illustration. It should also be noted that the method shown in FIGS. 3A-3T may start with the structure shown in FIG. 2F, with the nitride layer 214, the oxide layer 212, the hard mask layer 206 and the padding layer 204 removed. The STI regions 216 may still be formed, though later in the processing. As an alternative, the starting structure for FIGS. 3A-3T may include an SOI substrate, where a buried oxide layer replaces the buried epitaxial layer (e.g., a buried silicon germanium layer such as epitaxial layer 208).

FIGS. 3A-1 to 3A-3 shows multiple views of a semiconductor structure 300, including a perspective view and respective cross-sectional views taken along the lines A-A and B-B as shown in the isometric view of FIG. 3A-1. FIG. 3A-2 shows the A-A cross-sectional view taken along the L-direction similar to the cross-sectional view of FIG. 1A. FIG. 3A-3 shows the B-B cross-sectional view taken along the W-direction similar to the cross-sectional views of FIGS. 1B and 1C.

The A-A view of semiconductor structure 300 in FIG. 3A-2 includes an epitaxial layer 302, an epitaxial layer 304, and a drain drift region 306. The drain drift region 306 is not visible in the B-B view of semiconductor structure 300 in FIG. 3A-2. The epitaxial layer 302 is an example of the epitaxial layer 106 or the epitaxial layer 202, and the epitaxial layer 304 is an example of the epitaxial layer 108 or the epitaxial layer 208. The epitaxial layer 302 may be formed of silicon with the first conductivity type (e.g., p-type), while the epitaxial layer 304 may be formed of a compound semiconductor such as silicon germanium. The drain drift region 306 has the second conductivity type (e.g., n-type), and is formed within the epitaxial layer 302 using one or more ion implant processes, such as using an implant mask and one or more ion implant and anneal processes. The drain drift region 306 may have an average dopant density of about 1×10¹⁵ cm⁻³ to about 1×10¹⁷ cm⁻³, and more specifically, about 5×10¹⁵ cm⁻³ to about 5×10¹⁶ cm⁻³. The drain drift region 306 may have a heavier-doped top portion and a lighter doped bottom portion, to provide desired values of breakdown voltage and specific resistance for an LDMOS device.

As will be discussed in further detail below, a portion of the epitaxial layer 302 will become or provide a channel region for an LDMOS device. A bottom of the channel region will be defined by a buried isolation layer (e.g., similar to the buried isolation layer 119 of the LDMOS transistor 100 of FIGS. 1A-1C), with the buried isolation layer providing sufficient separation of the channel region from a remainder of the epitaxial layer 302 in order to reduce short channel effects. The thickness of the channel region may be selected based on whether the LDMOS device that is formed is intended to have a fully depleted (FD) channel region during operation or a partially depleted (PD) channel region during operation. For a FD channel region, the required thickness of the channel region is less than that for a PD channel region.

FIGS. 3B-1 and 3B-2 respectively show the A-A and B-B cross-sectional views of the semiconductor structure 300 of FIGS. 3A-2 and 3A-3 following formation of fins 303 in the epitaxial layer 302, where the fins 303 extend across the structure in the L-direction through the drain drift region 306. The A-A cross-sectional view, as shown, is taken along one of the fins 303. The fins 303 may be formed using various types of processing, including self-aligned double patterning (SADP), self-aligned quadruple patterning (SAQP), or other suitable patterning approaches.

In some examples, a patterning layer is formed over the structure, followed by a set of mandrels over the patterning layer. A first spacer is then formed over the mandrels (e.g., hard mandrels of a hard mask material) and the patterning layer. The first spacer is then etched such that it remains on sidewalls of the mandrels. The mandrels are then removed, followed by transferring the pattern of the remaining portions of the first spacer into the patterning layer to form mandrels of the patterning layer. A second spacer is then formed over the mandrels of the patterning layer, followed by etching of the second spacer such that it remains on the sidewalls of the mandrels of the patterning layer. The mandrels of the patterning layer are then removed, followed by transferring the patterning of the remaining portions of the second spacer to the underlying epitaxial layer 302 providing the fins 303. In other examples, organic mandrel etch processing is used, where the first spacer is formed over organic mandrels, followed by etching of the first spacer to remain on sidewalls of the organic mandrels. The organic mandrels are then removed, followed by forming a second spacer over remaining portions of the first spacer. The second spacer is then etched such that it remains on sidewalls of the remaining portions of the first spacer. The remaining portions of the first spacer are then removed, followed by transferring the pattern of the remaining portions of the second spacer to the underlying epitaxial layer 302 providing the fins 303.

As shown in FIG. 3B-2, the portion of the epitaxial layer 302 which remains above the epitaxial layer 304 includes a planar or nanosheet portion 305 and the fins 303 over the planar or nanosheet portion. In some embodiments, an etch stop layer is formed over the epitaxial layer 302, where the etch stop layer may be formed of silicon germanium. The etch stop layer facilitates formation of the planar or nanosheet portion 305 of the epitaxial layer 302 with a uniform thickness, and formation of the fins 303 with a uniform height. Selective etch processing may be used, where the etch rate of silicon (e.g., the material of the epitaxial layer 302) to the material of the etch stop layer (e.g., silicon germanium with a germanium percentage of about 20%) is greater than 200:1.

The planar or nanosheet portion 305 of the epitaxial layer 302 above the epitaxial layer 304 may have a thickness of about 50 to 200 nm. Each of the fins 303 may have a width of about 100 to 400 nm, and a height of about 100 to 700 nm. The width of the fins 303 may be thicker (e.g., about 1.5 to 2 times thicker) than the planar or nanosheet portion 305 of the epitaxial layer 302, due to the gate electrode being formed on both sides of the fins 303 as discussed in further detail below.

In some examples, the channel doping may be as low as about 5×10¹⁶ to 1×10¹⁹ cm⁻³, depending on the thickness of the channel. For an LDMOS transistor device, the silicon thickness may need to be relatively thick to achieve a desired current and threshold voltage. Thus, the channel doping may need to go up to about 4×10¹⁸ to 1×10¹⁹ cm^{×3}. This range may work for smaller channel widths without increasing the drain to source current I_{ds}, due to the presence of the planar or nanosheet portion 305 of the epitaxial layer 302 below the fins 303.

FIGS. 3C-1 and 3C-2 respectively show the A-A and B-B cross-sectional views of the semiconductor structure 300 following formation of a gate dielectric layer 308 and a field relief dielectric layer 310. The gate dielectric layer 308 (e.g., an example of the gate dielectric layer 120 of the LDMOS transistor 100 of FIGS. 1A-1C) and the field relief dielectric layer 310 (e.g., an example of the field relief dielectric layer 122 of the LDMOS transistor 100 of FIGS. 1A-1C) may be blanket deposited over the structure, surrounding the fins 303 as illustrated in the B-B cross-sectional view. The gate dielectric layer 308 may be a thermal oxide or a deposited high-k dielectric material, while the field relief dielectric layer 310 may be a low-k dielectric material. The gate dielectric layer 308 may have a thickness of about 1.5 to 30 nm, and the field relief dielectric layer 310 may have a thickness of about 30 to 300 nm.

In some examples, the gate dielectric layer 308 is formed of dielectric materials such as silicon dioxide, hafnium oxide, zirconium oxide, combinations thereof, etc. The gate dielectric layer 308 may be formed by thermal oxidation, one or more CVD processes, exposure to a nitrogen-containing plasma, etc.

In some examples, the field relief dielectric layer 310 is formed of an oxide such as silicon oxide or a nitride such as silicon nitride and/or silicon oxynitride, etc. The field relief dielectric layer 310 may be a low-k dielectric material having a dielectric constant of about 2.2 to 2.7. The field relief dielectric layer 310 may be formed on the gate dielectric layer 308 using one or more CVD processes, one or more physical vapor deposition (PVD) processes, one or more plasma-enhanced CVD (PECVD) processes, etc. In some examples, the field relief dielectric layer 310 is grown using a furnace thermal oxidation process. Growing the field relief dielectric layer 310 may include ramping a temperature of a furnace to about 900° C. to 1100° C. The ramping of the temperature may occur over about 45 minutes to about 90 minutes. The furnace may have an ambient oxygen percentage of about 1% to 15%, and more specifically about 2% to 10%. While maintaining the temperature of the furnace, the percentage of ambient oxygen may be increased to about 80% to 95% over about 5 to 30 minutes, and more specifically, about 10 to 20 minutes. In various examples, a hydrogen chloride gas may be introduced to the furnace while maintaining the ambient oxygen percentage of the furnace. In various examples, a nitrogen gas may be introduced to the furnace to purge the ambient oxygen so that the temperature of the furnace ramps down in a nitrogen rich environment.

FIGS. 3D-1 and 3D-2 respectively show the A-A and B-B cross-sectional views of the semiconductor structure 300 following patterning of the field relief dielectric layer 310. The field relief dielectric layer 310 may be patterned by forming a mask layer (e.g., a photoresist layer) over a part of the structure, and etching portions of the field relief dielectric layer 310 exposed by the patterned mask layer down to the gate dielectric layer 308 (e.g., over where the channel and source regions of the LDMOS device will be formed).

FIGS. 3E-1 and 3E-2 respectively show the A-A and B-B cross-sectional views of the semiconductor structure 300 following formation of a dielectric layer 312. The dielectric layer 312 may be deposited over the structure. The dielectric layer 312 may be an oxide or nitride material. The dielectric layer 312 may have a thickness of about 30 to 300 nm.

FIGS. 3F-1 and 3F2 respectively show the A-A and B-B cross-sectional views of the semiconductor structure 300 following etching of the dielectric layer 312, with the remaining portion of the dielectric layer 312 providing a dielectric spacer (referred to as dielectric spacer 312, which is an example of the dielectric spacer 124 of the LDMOS transistor 100 of FIGS. 1A-1C) on the sidewall of the field relief dielectric layer 310 that is proximate to where the channel and source regions of the LDMOS device will be formed. The etching may be an anisotropic etch process (e.g., a plasma etch process, a reactive-ion etch (RIE) process, etc.) that removes the material of the dielectric layer 312 from horizontal areas, while leaving the material of the dielectric layer 312 on the vertical area (i.e., the sidewall of the field relief dielectric layer 310). The dielectric spacer 312 is shown in the A-A cross sectional view as having a height that is less than that of the field relief dielectric layer 310, but this is not a requirement. In other examples, the dielectric spacer 312 may have the same height as the field relief dielectric layer 310.

FIGS. 3G-1 and 3G-2 respectively show the A-A and B-B cross-sectional views of the semiconductor structure 300 following formation of a gate electrode 314 (e.g., an example of the gate electrode 126 of the LDMOS transistor 100 of FIGS. 1A-1C) and a hard mask layer 316 (e.g., an example of the gate hard mask 127 of the LDMOS transistor 100 of FIGS. 1A-1C). The gate electrode 314 may be formed of polycrystalline silicon (also referred to as polysilicon), titanium nitride, other metals or metal alloys, etc. In some examples, the gate electrode 314 is doped with n-type or p-type dopants depending on the polarity of other materials. The gate electrode 314 may have a thickness of about 200 to 900 nm, and more specifically about 300 to 800 nm. The hard mask layer 316 may be formed of silicon nitride, silicon oxynitride, or high-k dielectric materials such as hafnium oxide that provides better etch selectivity. The hard mask layer 316, in some examples, is a multi-stack layer that can provide different selectivity for multiple different etch processes. The hard mask layer 316 may have a thickness of about 50 to 200 nm.

FIG. 3H shows the A-A cross-sectional view of the semiconductor structure 300 following patterning of the gate electrode 314 and the hard mask layer 316 to open the source area. A mask layer may be formed over the hard mask layer 316, and exposed portions of the hard mask layer 316 and the gate electrode 314 may be etched to reveal the gate dielectric layer 308 in the area where the source region of the LDMOS device will be formed.

FIG. 3I shows the A-A cross-sectional view of the semiconductor structure 300 following formation of a nitride layer 318. The nitride layer 318 may be formed of a nitride material or a high-k dielectric material, and may have a thickness of about 20 to 200 nm.

FIG. 3J shows the A-A cross-sectional view of the semiconductor structure 300 following formation of a nitride spacer from the nitride layer 318, and following etching of exposed portions of the gate dielectric layer 308 and the underlying epitaxial layers 302 and 304. The etching of the nitride layer 318 may be an anisotropic etch process that removes the material of the nitride layer 318 from horizontal areas, while leaving the material of the nitride layer 318 on the vertical area (i.e., the sidewall of the gate electrode 314 and the hard mask layer 316). The remaining portion of the nitride layer 318 is also referred to as a nitride spacer 318 (e.g., an example of the gate spacer 128 of the LDMOS transistor 100 of FIGS. 1A-1C). The gate dielectric layer 308 and the underlying epitaxial layers 302 and 304 may be removed using suitable etch processing.

FIG. 3K shows the A-A cross-sectional view of the semiconductor structure 300 following formation of an oxide layer 320. The oxide layer 320 may be formed of an oxide material, and may have a thickness of about 50 to 200 nm. The oxide layer 320 may be replaced with a nitride layer, if the spacer 318 is a high-k material.

FIG. 3L shows the A-A cross-sectional view of the semiconductor structure 300 following formation of an oxide spacer from the oxide layer 320. The oxide spacer may be formed by etching the oxide layer 320 using an anisotropic etch process that removes the material of the oxide layer 320 from horizontal areas, while leaving the material of the oxide layer 320 on the vertical area (i.e., the sidewall of the nitride spacer 318 and the epitaxial layers 302 and 304. The exposed area of the epitaxial layer 302 may then be further etched using one or more etch processes to a depth which is below the bottom surface of the epitaxial layer 304.

FIG. 3M shows the A-A cross-sectional view of the semiconductor structure 300 following an etching which removes the material of the epitaxial layer 302 selective to the material of the epitaxial layer 304. This etching may have a selectivity of about 100:1 or greater for the material of the epitaxial layer 302 (e.g., silicon) to the material of the epitaxial layer 304 (e.g., silicon germanium). The selective etching of the epitaxial layer 302 results in an undercut region 321 below the bottom surface of the oxide layer 320 and the epitaxial layer 304. To perform a silicon etch that is selective with silicon germanium, the etching process may have a silicon to silicon germanium (Si:SiGe) etch ratio of about 200:1, such that little to no material is removed from epitaxial layer 604 during the etching of the epitaxial layer 602. In some examples, the one or more etching processes may include the use of tetrafluoromethane (CF₄), nitrogen (N₂), oxygen (O₂), and/or difluoromethane (CH₂F₂), among other etchants. The one or more etching processes may utilize an etch pressure from about 150 to 1500 mTorr (20-200 Pa).

FIG. 3N shows the A-A cross-sectional view of the semiconductor structure 300 following an etching which removes the material of the epitaxial layer 304 selective to the material of the epitaxial layer 302 to form a lateral gap 323. The selective etching of the epitaxial layer 304 may use a mixture of hydrofluoric acid (HF), hydrogen peroxide (H₂O₂) and acetic acid (CH₃COOH), which has a selectivity of about 79:1 for the material of the epitaxial layer 304 (e.g., silicon germanium) to the material of the epitaxial layer 302 (e.g., silicon). To perform a selective etching of silicon germanium, in some examples, several etch processes may be used including a selective vapor phase etching with a high partial pressure of hydrochloric acid (HCl) at a pressure of about 100 to 400 Torr (13 to 50 kPa), or a mixture of CF₄/O2/He plasma at a low pressure between about 5 to 150 mTorr (0.7-20 Pa). In a wet etch process, a mixed solution containing water (H₂O), nitric acid (HNO₃), acetic acid (CH₃COOH) and HF may be used.

FIG. 3O shows the A-A cross-sectional view of the semiconductor structure 300 following deposition of additional oxide material for the oxide layer 320. The additional oxide material may be deposited using atomic layer deposition (ALD) to fill in the lateral gap 323, followed by a flowable oxide deposition process to fill in the remainder of the structure as shown.

FIG. 3P shows the A-A cross-sectional view of the semiconductor structure 300 following etching of the oxide layer 320. The oxide layer 320 may be etched using an anisotropic etch process which removes the material of the oxide layer 320 from horizontal areas, while leaving the material of the oxide layer 320 on the vertical area (e.g., filling in the lateral gap 323 and the undercut region 321). The remaining portion of the oxide layer 320 provides a buried isolation spacer (e.g., an example of the buried isolation layer 119 of the LDMOS transistor 100 of FIGS. 1A-1C).

FIG. 3Q shows the A-A cross-sectional view of the semiconductor structure 300 following a selective growth of epitaxial layer 322 over the epitaxial layer 302. In some examples, there is a seam or void 325 between the epitaxial layer 302 and the epitaxial layer 322. The seam or void 325, however, is in the source area which is the lower voltage side for an LDMOS device. In other examples, there is no seam or void 325, as the epitaxial layer 322 may be formed by deposition of amorphous silicon followed by etch and recess, and regrowing silicon crystal to avoid the seam or void 325. The epitaxial growth of the epitaxial layer 322 utilize a molecular beam epitaxy (MBE) process, a chemical vapor deposition (CVD) process, a metalorganic chemical vapor deposition (MOCVD) process, other suitable epitaxial growth process, or combinations thereof.

FIG. 3R shows the A-A cross-sectional view of the semiconductor structure 300 following gate patterning. A mask layer (not shown) is patterned over the structure, followed by removal of portions of the hard mask layer 316 and the gate electrode 314 which are exposed by the mask layer, revealing part of the field relief dielectric layer 310 formed over the drain drift region 306 proximate where the drain region of the LDMOS device will be formed. The mask layer is then removed.

FIG. 3S shows the A-A cross-sectional view of the semiconductor structure 300 following an optional formation of a drain-side gate spacer 318, and following patterning and etching of the field relief dielectric layer 310. The drain-side gate spacer 318 may be formed of similar materials and with similar processing as that described above with respect to FIGS. 3I and 3J for formation of the source-side gate spacer 318. The field relief dielectric layer 310 may be patterned by forming a mask layer (not shown) over the structure, and etching portions of the field relief dielectric layer 310 exposed by the mask layer, followed by removal of the mask layer.

FIGS. 3T-1 and 3T-2 respectively show the A-A and B-B cross-sectional views of the semiconductor structure 300 following formation of epitaxial layers 324 and 326 for a super junction proximate the drain area, and following formation of drain region 328, well region 330, source region 332 and body contact region 334. FIG. 3T also shows a C-C cross-sectional view, which is taken in the W-direction along where the super junction is formed proximate the drain region 328. The super junction formation includes selective growth of an epitaxial layer 326 over the fins 303 of the drain drift region 306 which are exposed by the patterning of the field relief dielectric layer 310, and formation of epitaxial layer 326 over the epitaxial layer 324. The epitaxial layer 324 is undoped or lightly doped (e.g., having a doping concentration that is less than that of the drain drift region 306 and the epitaxial layer 326), and the epitaxial layer 328 has the first conductivity type (e.g., p-type). The drain region 328, the well region 330, the source region 332 and the body contact region 334 are then formed using ion implant processing. The structure shown in FIG. 3T may be subject to further processing to form silicide layers, an ILD layer and contacts (e.g., silicide layers 134, ILD layer 136 and contacts 138 of the LDMOS transistor 100 of FIGS. 1A-1C).

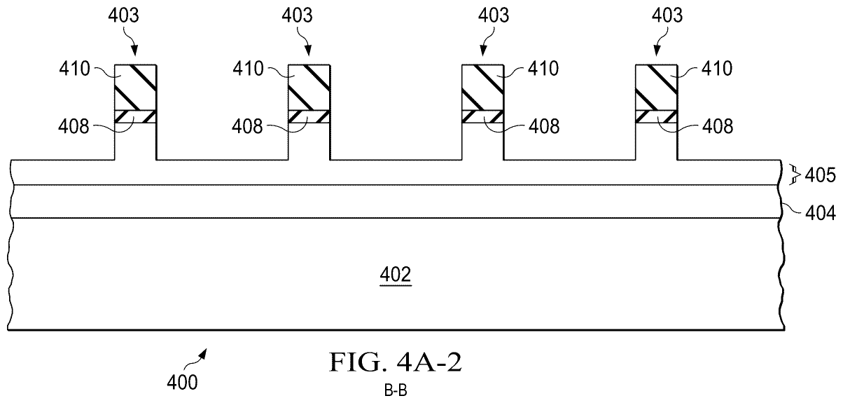

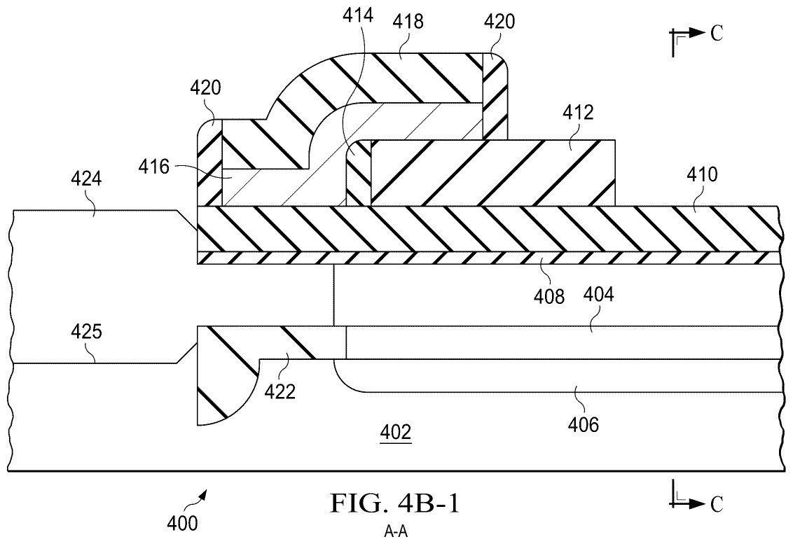

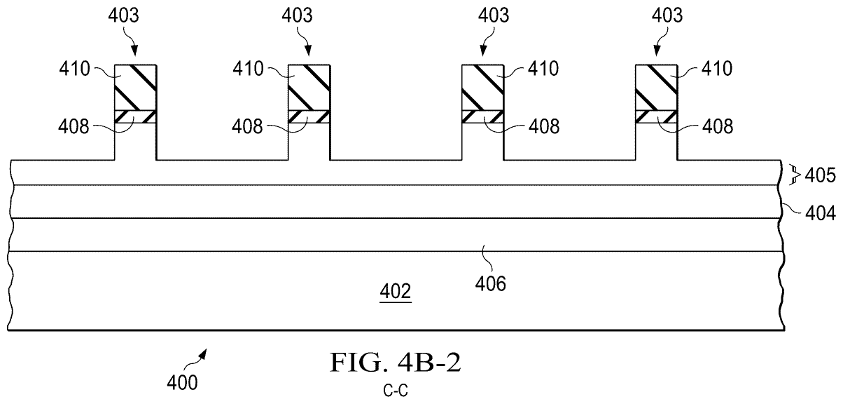

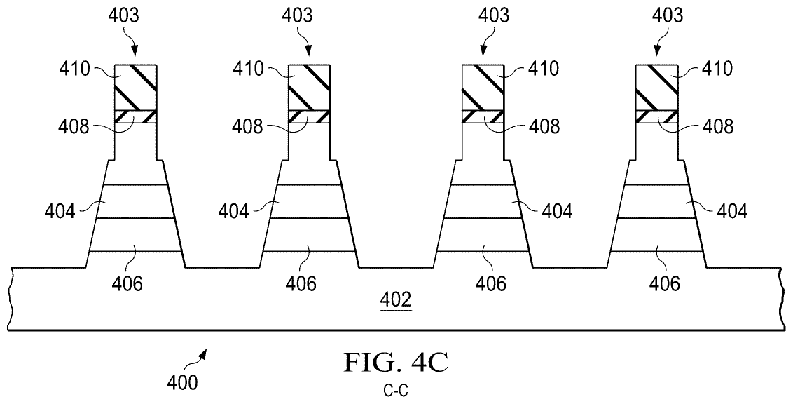

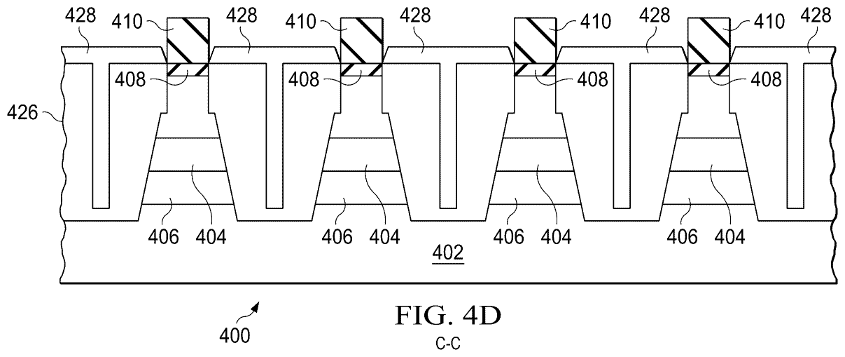

Referring now to FIGS. 4A-4D, a method of fabricating an LDMOS device with a buried isolation layer (e.g., buried isolation layer 119) and an extended super junction proximate a drain region is shown. Similar to FIGS. 3A-3T, the starting structure of FIGS. 4A-4D includes a portion of the structure of FIG. 2F or FIG. 2G between isolation regions 216 in which the epitaxial layer 208 is formed (with the nitride layer 214, the oxide layer 212, the hard mask layer 206 and the padding layer 204 having been removed). In some other examples, not explicitly shown, structures analogous to those shown in FIGS. 4A-4D may include an insulating layer such as in an SOI substrate, in which a buried oxide layer replaces the buried epitaxial layer of the heterogenous epitaxial layer.

FIGS. 4A-1 and 4A-2 show multiple views of a semiconductor structure 400, including respective cross-sectional views taken along the lines A-A and B-B as shown. The A-A cross-sectional view is a view taken along the L-direction similar to the cross-sectional view of FIG. 1A. The B-B cross-sectional view is a view taken along the W-direction similar to the cross-sectional views of FIG. 1B.

FIGS. 4A-1 and 4A-2 show a semiconductor structure 400 including an epitaxial layer 402, an epitaxial layer 404, a drain drift region 406, an oxide hard mask layer 408 and a nitride hard mask layer 410. The oxide hard mask layer 408 and the nitride hard mask layer 410 may be collectively referred to as a fin hard mask, utilized in patterning a set of fins 403 above a planar or nanosheet portion 405 of the epitaxial layer 402. The epitaxial layer 402, the epitaxial layer 404, the drain drift region 406, the fins 403 and the planar or nanosheet portion 405 of the epitaxial layer 402 may be formed with similar sizing and using similar processing as that described above with respect to formation of the epitaxial layer 302, the epitaxial layer 304, the drain drift region 306, the fins 303 and the planar or nanosheet portion 305 of the epitaxial layer 302.

FIG. 4B-1 shows the A-A cross-sectional view of the semiconductor structure 400 following formation of a field relief dielectric layer 412, spacer 414, gate electrode 416, hard mask 418, gate spacers 420, buried isolation layer 422 and epitaxial layer 424 along with a seam or void 425. FIG. 4B-2 shows a C-C cross-sectional view of the semiconductor structure 400, which is taken in the W-direction direction similar to the cross-sectional view of FIG. 1C along where the extended super junction will be formed proximate a drain region. The field relief dielectric layer 412, the spacer 414, the gate electrode 416, the hard mask 418, the gate spacers 420, the buried isolation layer 422, the epitaxial layer 424 and the seam or void 425 may be formed of similar materials and with similar processing as that described above with respect to the field relief dielectric layer 310, the dielectric spacer 312, the gate electrode 314, the hard mask layer 316, the nitride spacer 318, the buried isolation spacer 320, the epitaxial layer 322 and the seam or void 325, respectively, though the fin hard mask is not removed in the semiconductor structure 400.

FIG. 4C shows the C-C cross-sectional view of the semiconductor structure 400 following etching through the drain drift region 406, the epitaxial layer 404 and the epitaxial layer 402 in the area exposed by patterning of the field relief dielectric layer 412. The fin hard mask (the oxide hard mask layer 408 and the nitride hard mask layer 410) is used to etch through the material of the drain drift region 406 (e.g., silicon), the epitaxial layer 404 (e.g., silicon germanium) and partway through the underlying portion of the epitaxial layer 402 (potentially to a depth of a buried layer such as buried layer 104 in the LDMOS transistor 100 of FIGS. 1A-1C).

FIG. 4D shows the C-C cross-sectional view of the semiconductor structure 400 following formation of the extended super junction through growth of epitaxial layer 426 and epitaxial layer 428. The epitaxial layer 426, like the epitaxial layer 324, may be undoped silicon or lightly doped silicon (e.g., with a dopant concentration less than that of drain drift region 406 and the epitaxial layer 428). The epitaxial layer 428 has the first conductivity type (e.g., p-type). Compared with the semiconductor structure 300 of FIG. 3T, the super junction of the semiconductor structure 400 of FIG. 4D is “extended” or deeper due to the etching shown in FIG. 4C. The extended super junction may be used for higher voltage devices.

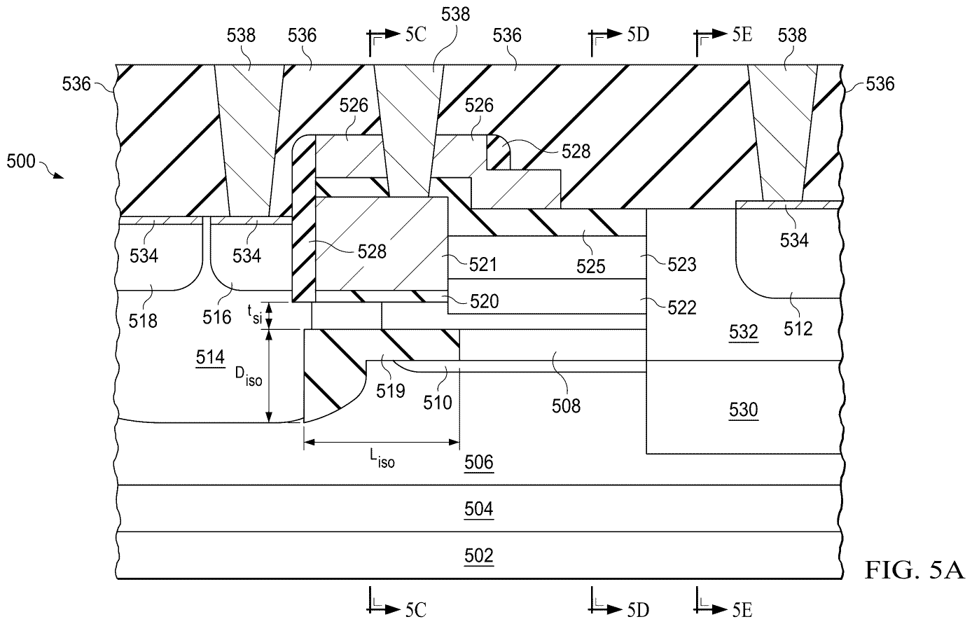

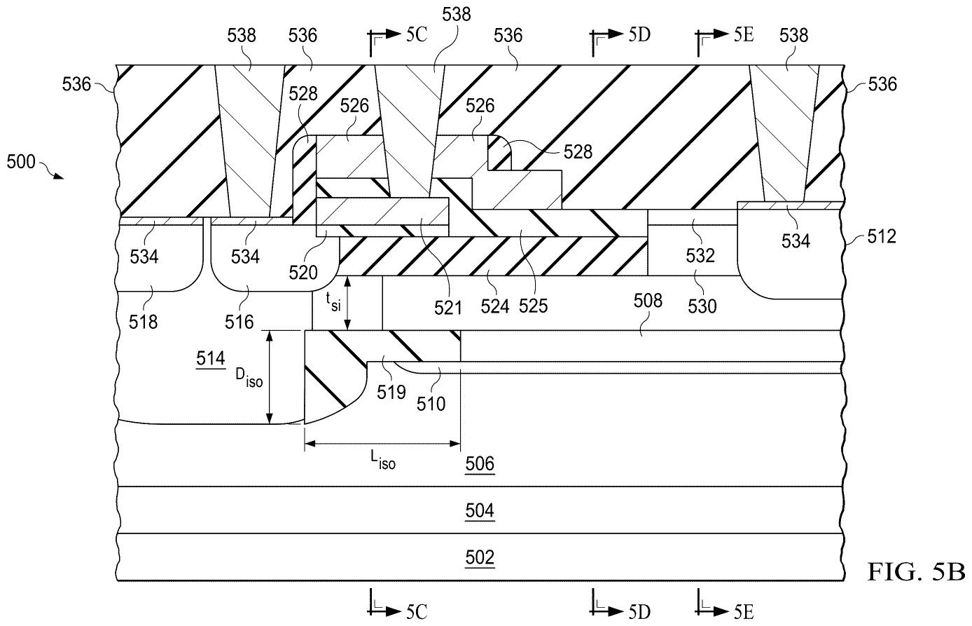

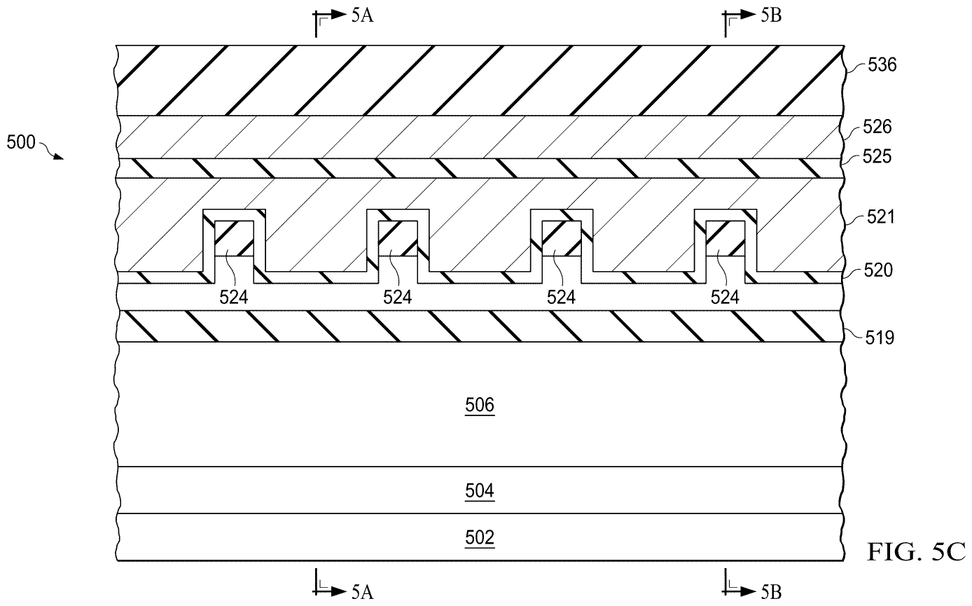

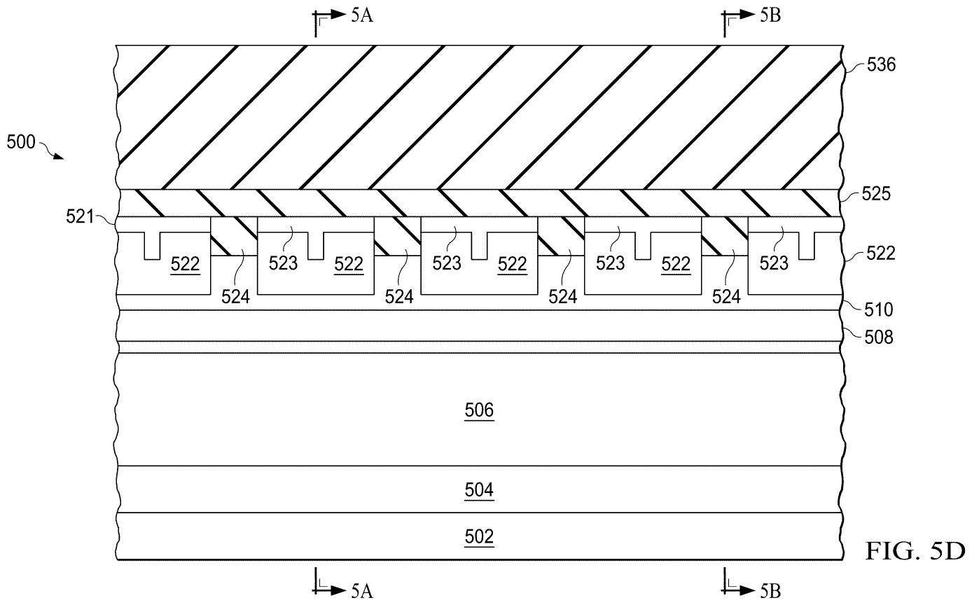

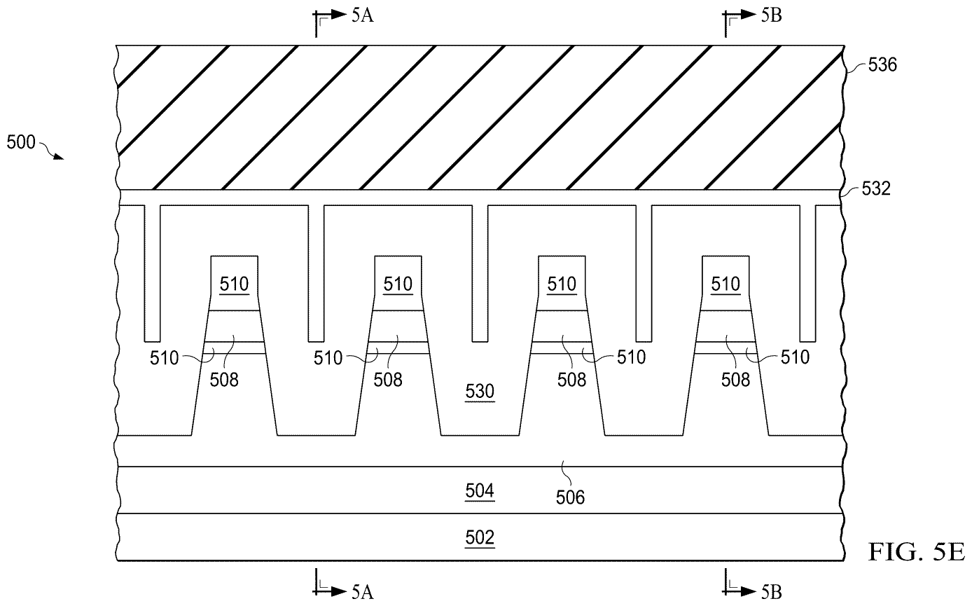

Referring now to FIGS. 5A-5E, an LDMOS transistor structure 500 is shown, in which FIGS. 5A and 5B show sectional views along the L-direction and FIGS. 5C-5E show section views along the W-direction as marked in FIGS. 5A and 5B. Collectively these figures include a substrate 502, a buried layer 504, an epitaxial layer 506, a channel region, an epitaxial layer 508, a heterogenous drain drift region 510 that includes the epitaxial layer 508, a drain region 512, a well region 514, a source region 516, a body (or back-gate) contact region 518, a buried isolation layer 519, a gate dielectric layer 520, a first electrode portion 521 (also referred to as a gate electrode), an epitaxial layer 522, an epitaxial layer 523, a fin hard mask 524, a field relief dielectric layer 525, a second electrode portion 526 (also referred to as a field plate electrode), gate spacers 528, an epitaxial layer 530, an epitaxial layer 532, silicide layers 534, ILD layer 536, and contacts 538. The substrate 502, the epitaxial layer 506, the body contact region 518, the epitaxial layer 523 and the epitaxial layer 532 are the first conductivity type (e.g., p-type), while the buried layer 504, the drain drift region 510, the drain region 512 and the source region 516 are the second conductivity type (e.g., n-type). The epitaxial layers 522 and 530 may be undoped, or may be lightly doped (e.g., with a dopant concentration less than that of the drain drift region 510, the epitaxial layer 523 and the epitaxial layer 532). An unreferenced portion of the second electrode portion 526 over the field relief dielectric layer 525 may be regarded as a field plate.

In the LDMOS transistor structure 500, the super junction has two sections: a first section disposed underneath the field relief dielectric layer 525 that is formed by the drain drift region 510, the epitaxial layer 522 and the epitaxial layer 523; and a second section disposed proximate the drain region 512 that is “extended” relative to the first section and which is formed by the drain drift region 510, the epitaxial layer 530 and the epitaxial layer 532. The first section of the super junction underneath the field relief dielectric layer 525 is shallower than the second section of the super junction proximate the drain region 512. The second section of the super junction proximate the drain region 512 may extend deep into the epitaxial layer 506 (potentially down to the buried layer 504). The first section of the super junction leads to the channel, while the second section of the super junction extends deep into the epitaxial layer 506 (potentially reaching the buried layer 504 providing electrical isolation).

The LDMOS transistor structure 500 is formed by providing the substrate 502 and forming the buried layer 504 over the substrate 502 and forming the epitaxial layer 506 over the buried layer 504. Optionally, the substrate 502 is p-type silicon, but may also be n-type silicon or SOI. The epitaxial layer 506 has the first conductivity type (e.g., p-type), while the buried layer 504 has the second conductivity type (e.g., n-type, and thus referred to without limitation as an n-type buried layer or NBL). The substrate 502, the buried layer 504 and the epitaxial layer 506 may be formed of silicon, and may also include other semiconducting material.

The epitaxial layer 508 may be formed by patterning an opening in the epitaxial layer 506, followed by deposition of a material for the epitaxial layer 508, followed by re-growth of the epitaxial layer 506 over the epitaxial layer 508. FIGS. 2A-2G show a process flow which may be used to form the epitaxial layer 508. The epitaxial layer 508 is formed of a material which may later be etched selective to that of the epitaxial layer 506. Where the epitaxial layer 506 is formed of silicon, the epitaxial layer 508 may be formed of silicon germanium.

The drain drift region 510, the drain region 512, the well region 514, the source region 516 and the body contact region 518 may each be formed using one or more ion implant processes (possibly with different energies) followed by optional anneal or thermal drive-in processes, with the use of suitable ion implant masks to form these regions in the locations shown in FIGS. 5A-5E. The drain drift region 510, the drain region 512 and the source region 516 may be the second conductivity type (e.g., n-type) while the well region 514 and the body contact region 518 may be the first conductivity type (e.g., p-type).

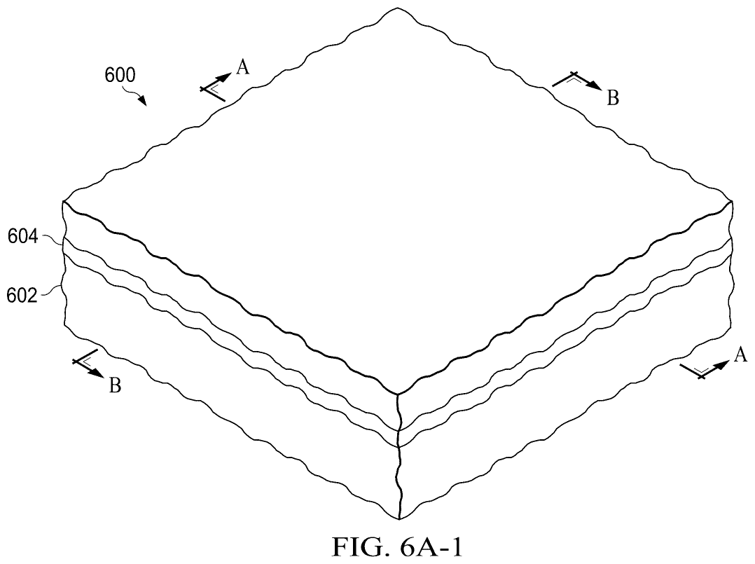

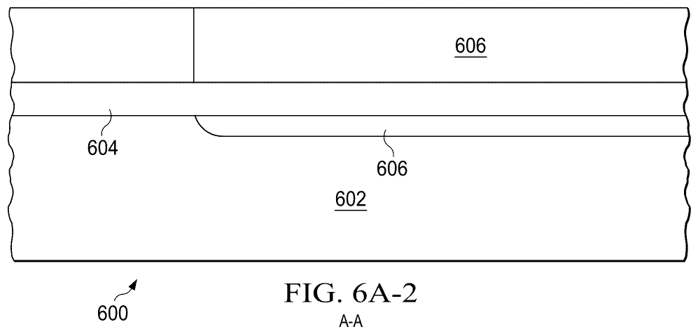

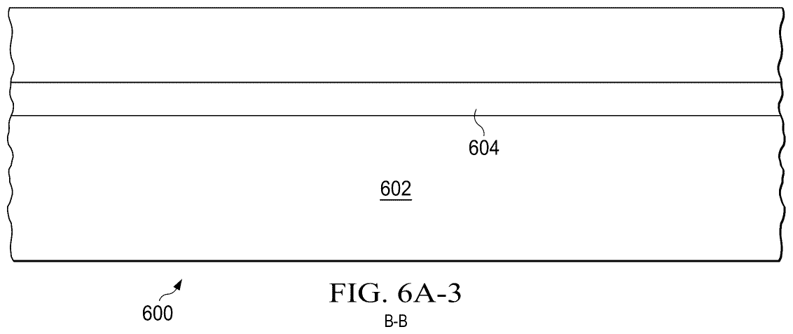

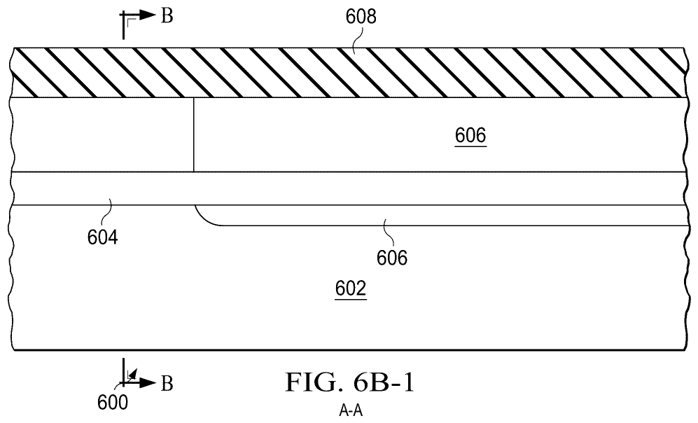

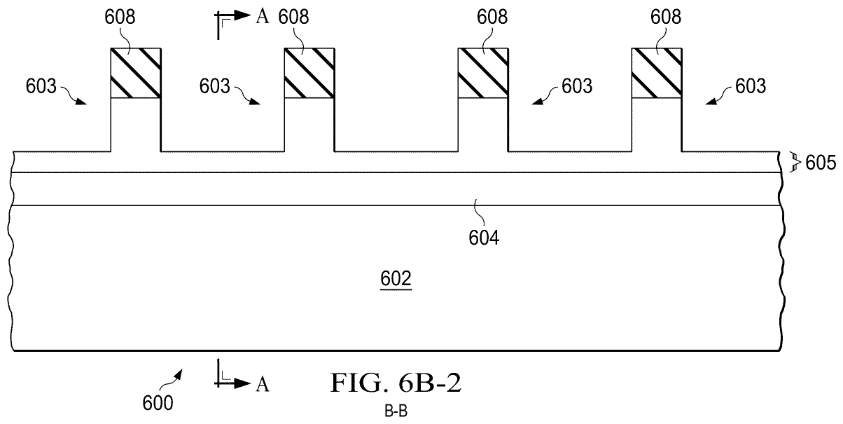

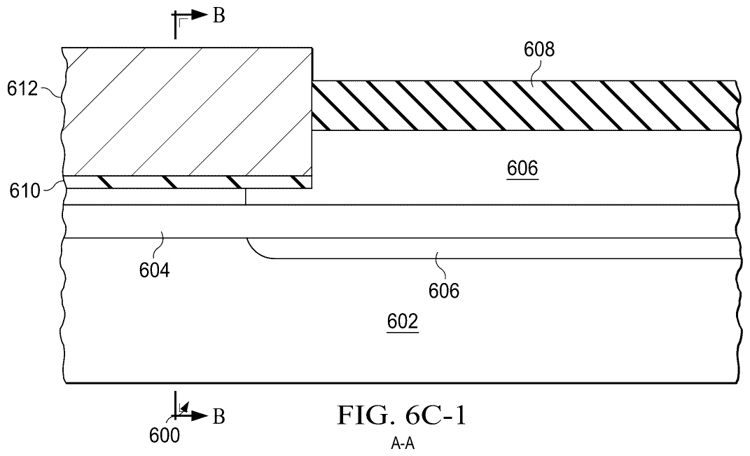

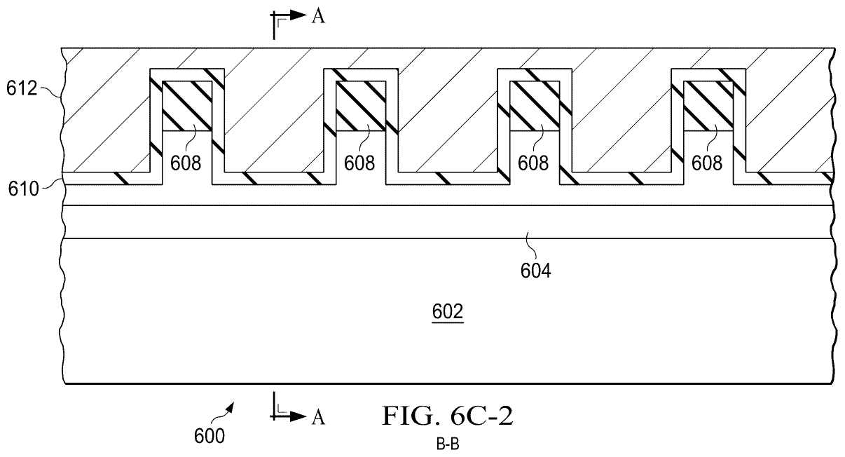

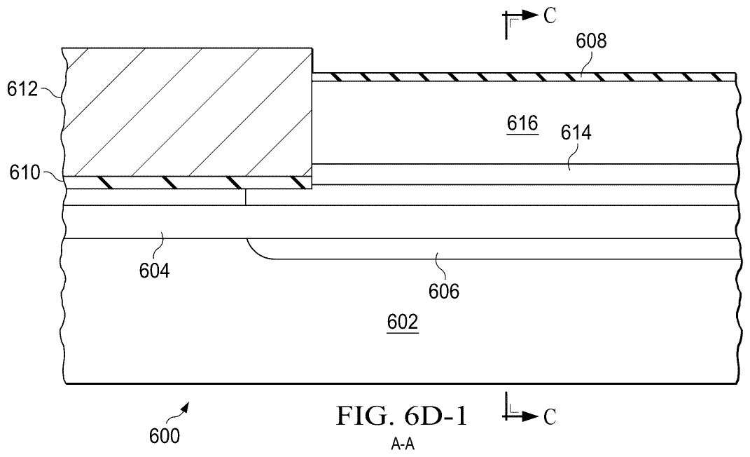

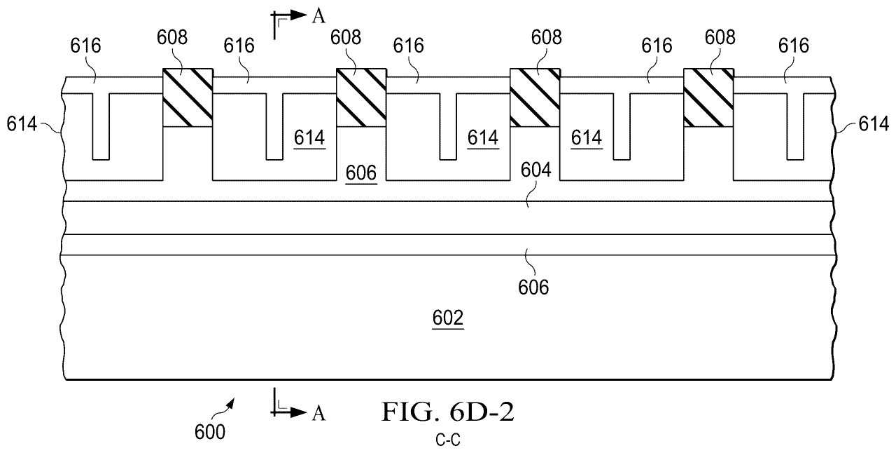

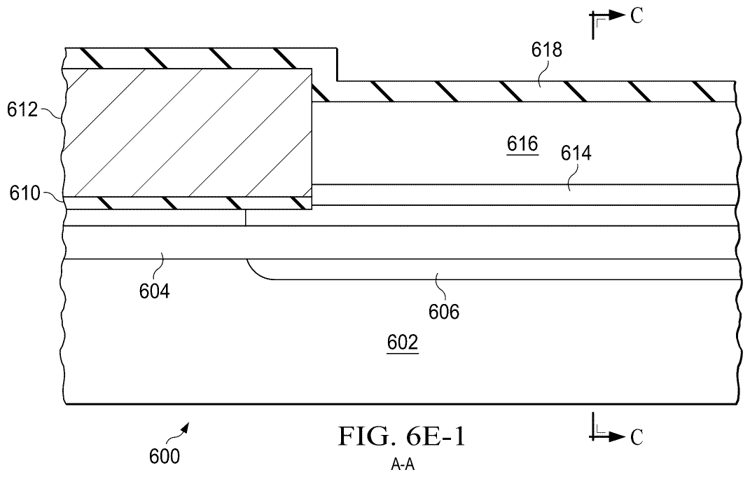

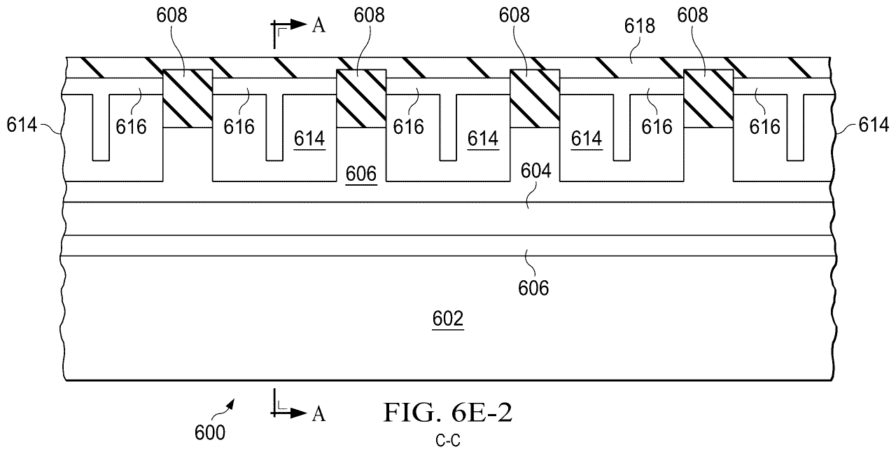

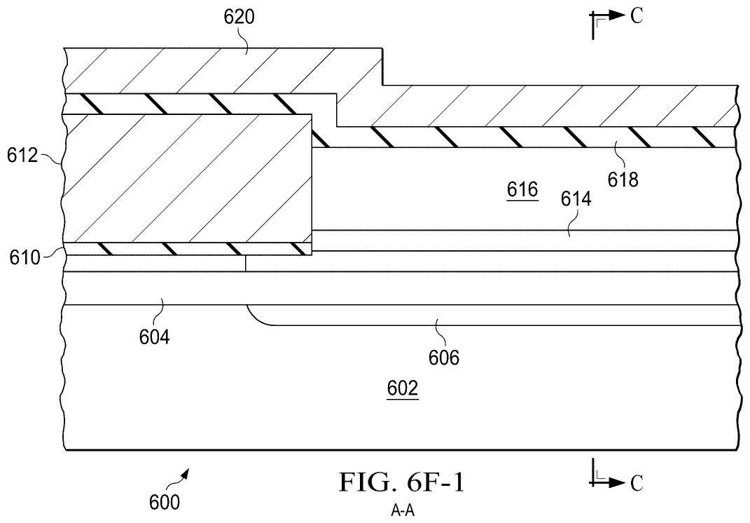

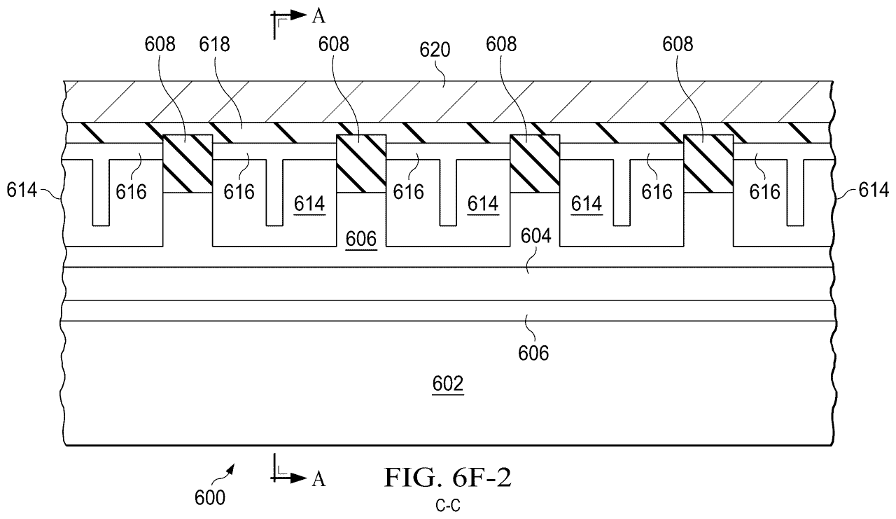

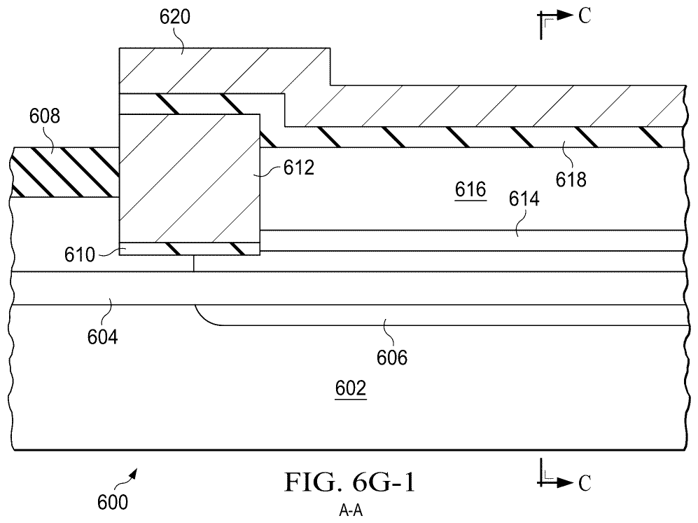

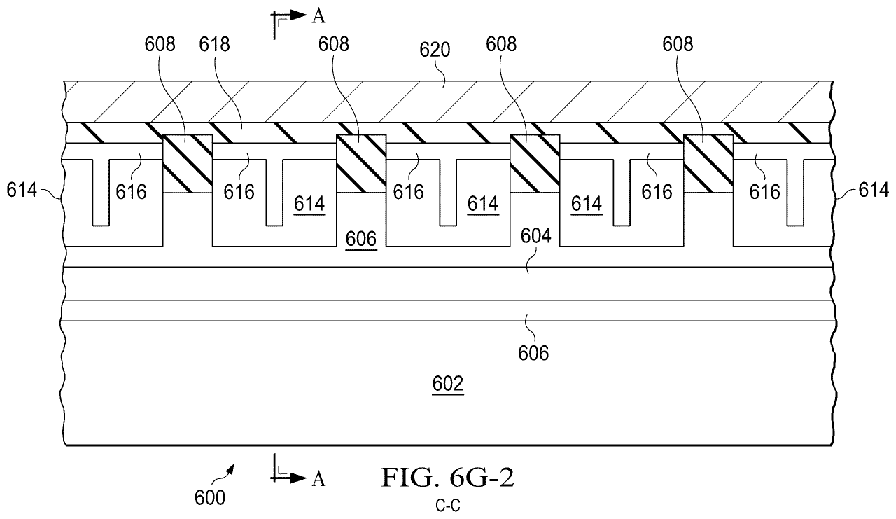

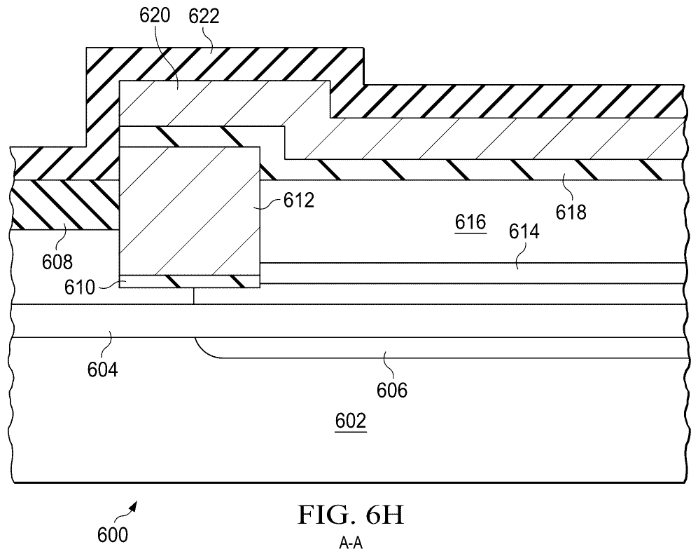

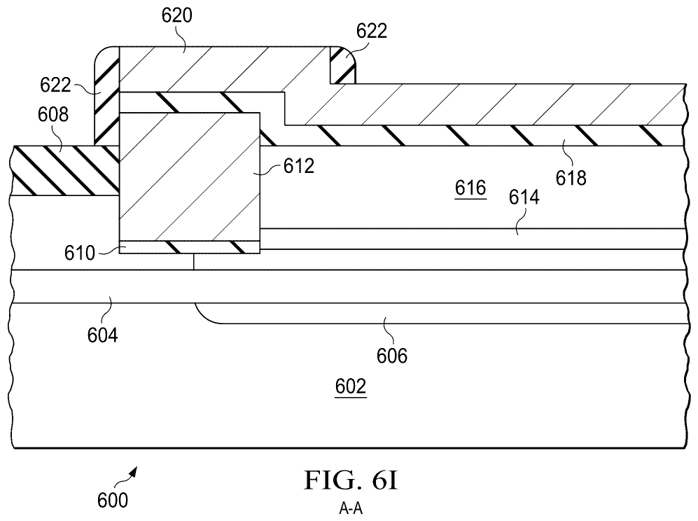

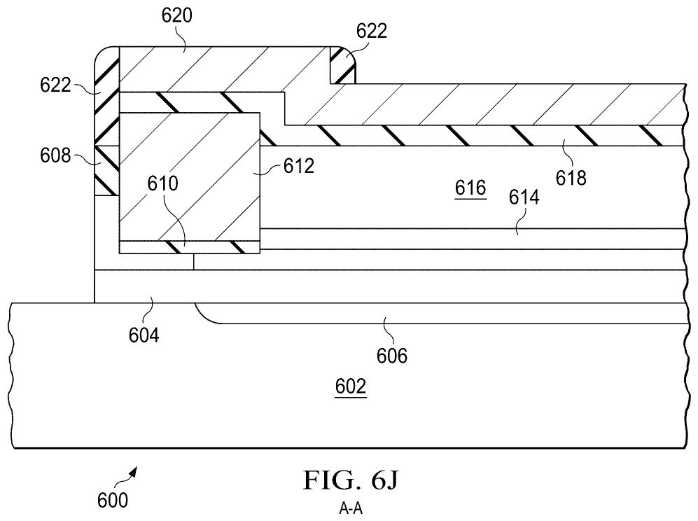

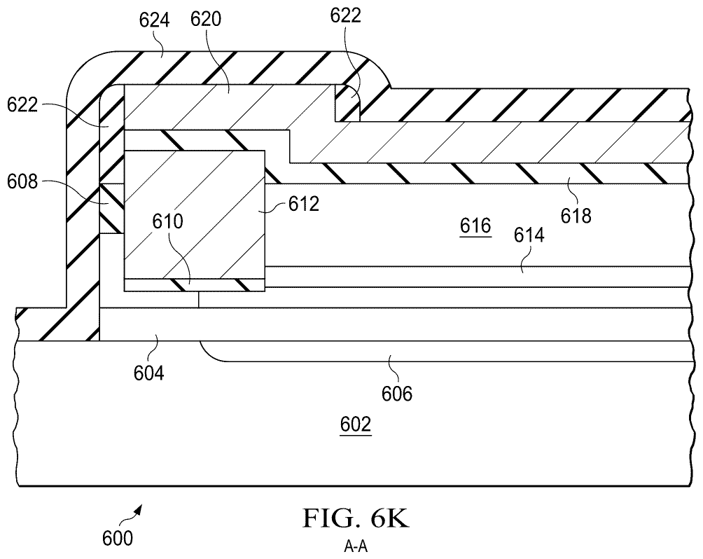

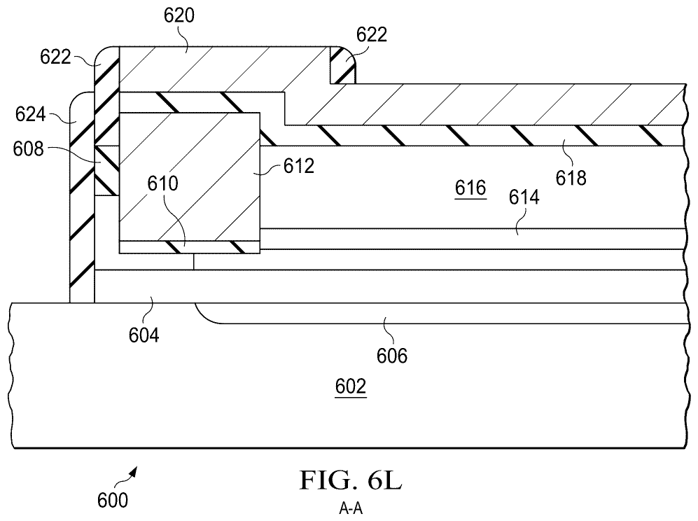

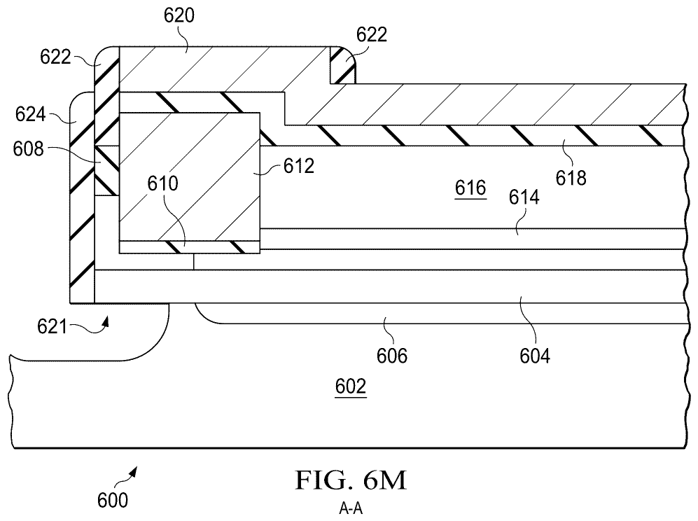

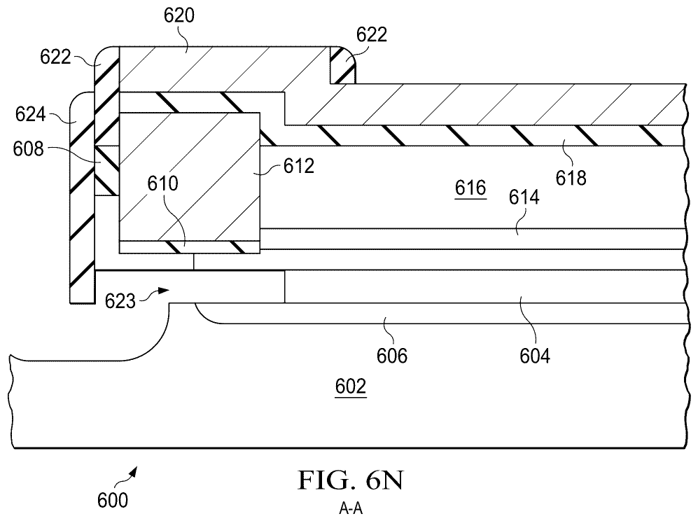

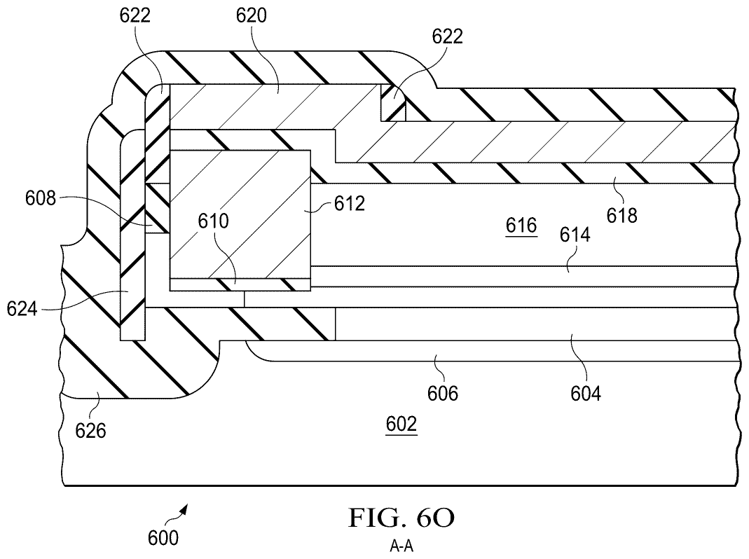

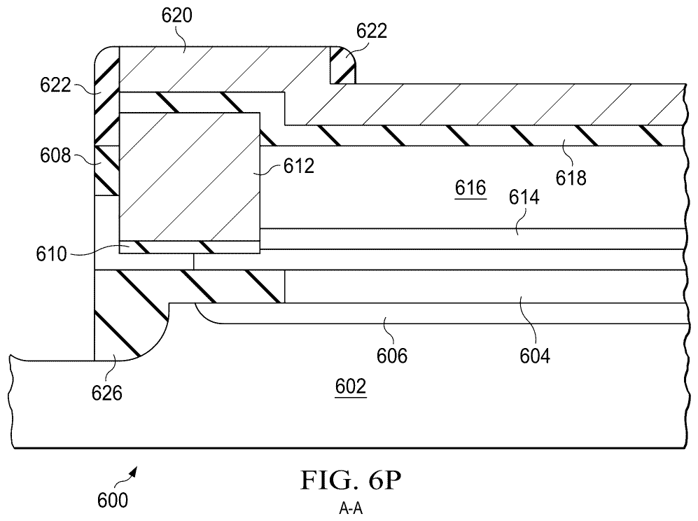

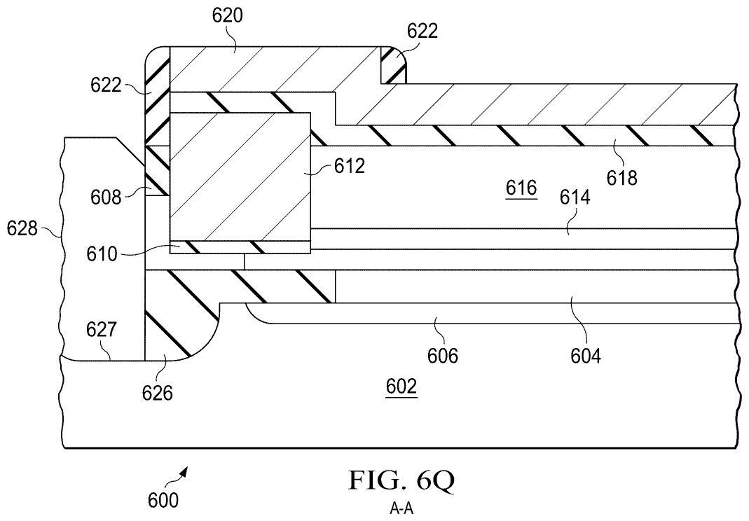

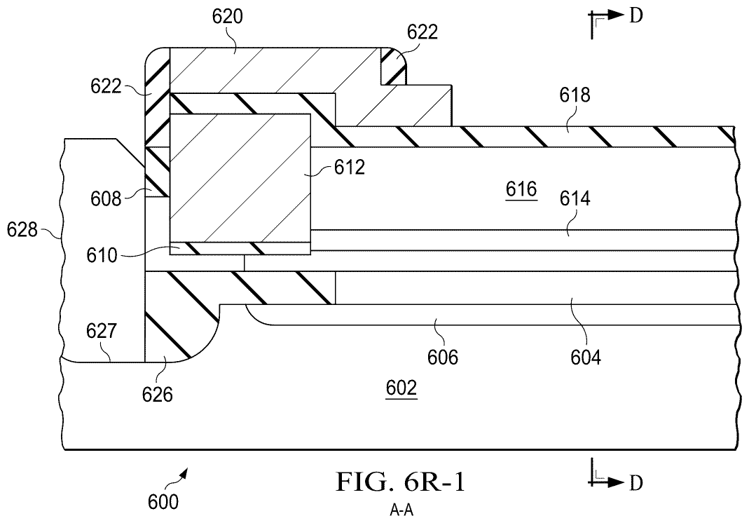

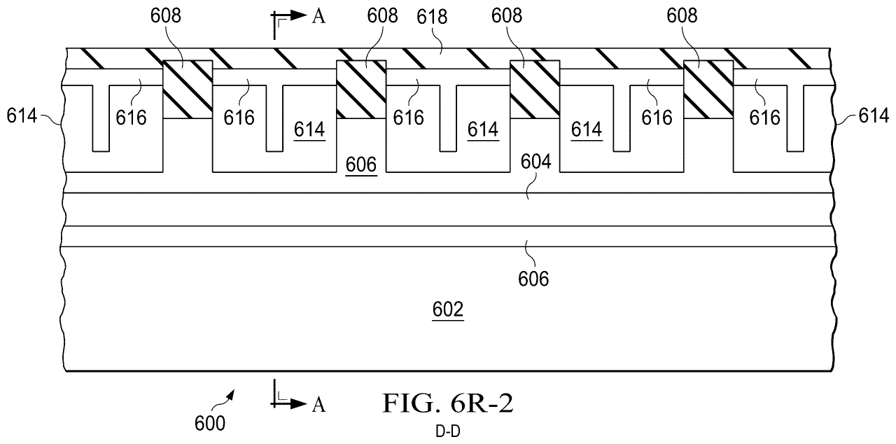

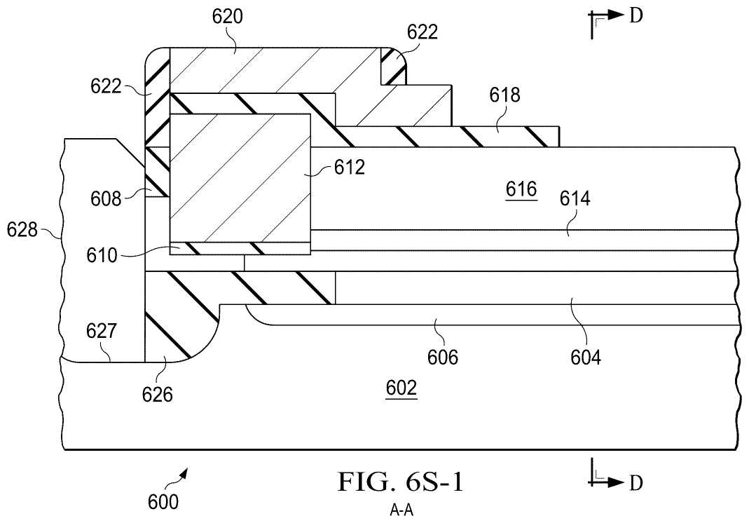

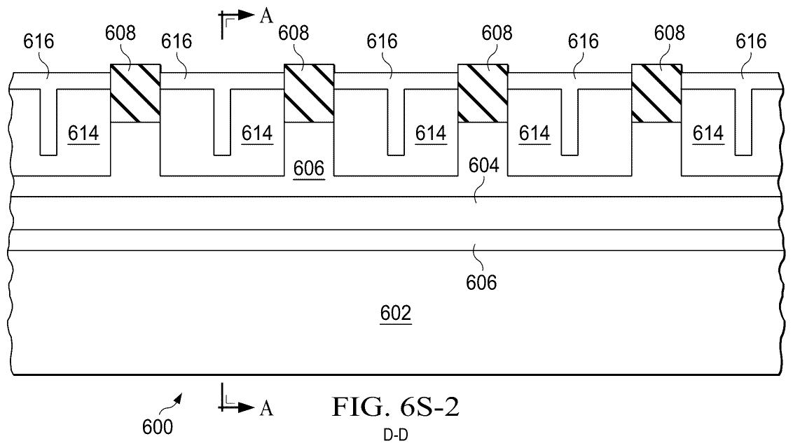

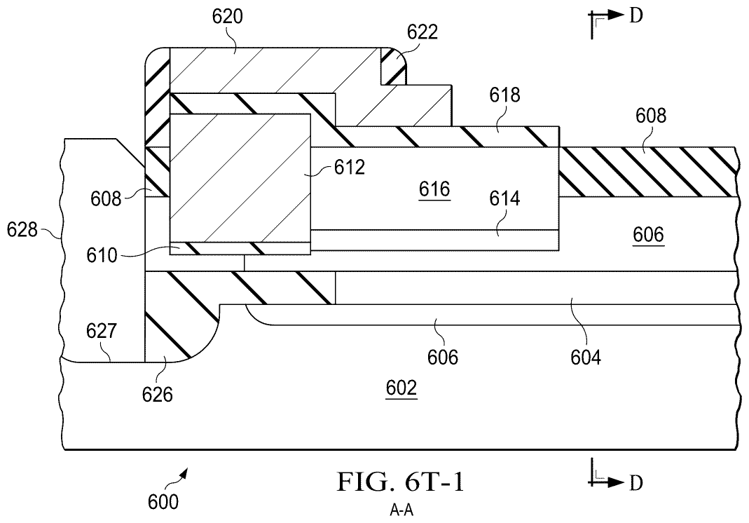

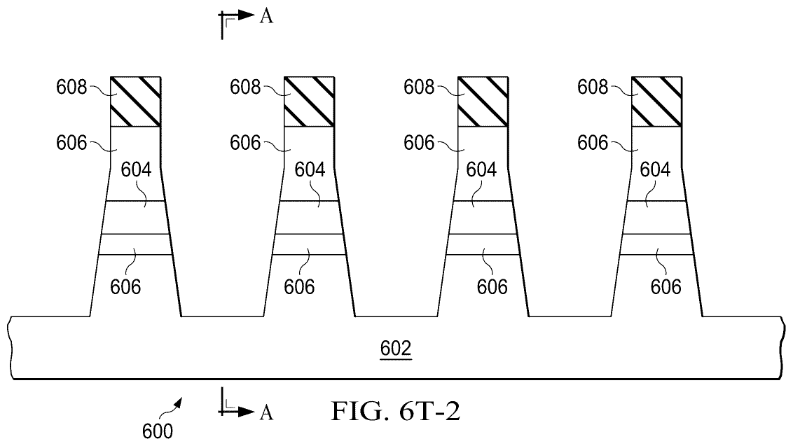

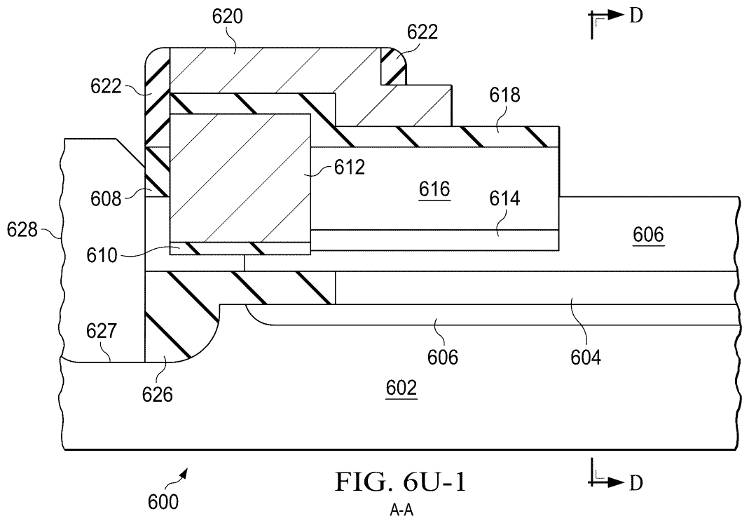

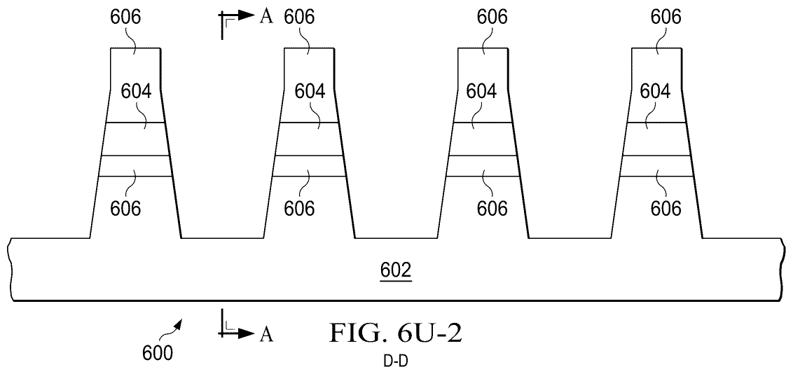

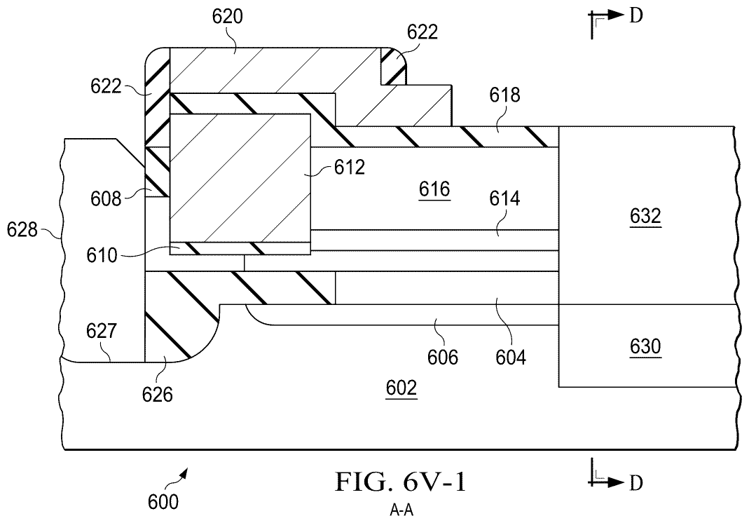

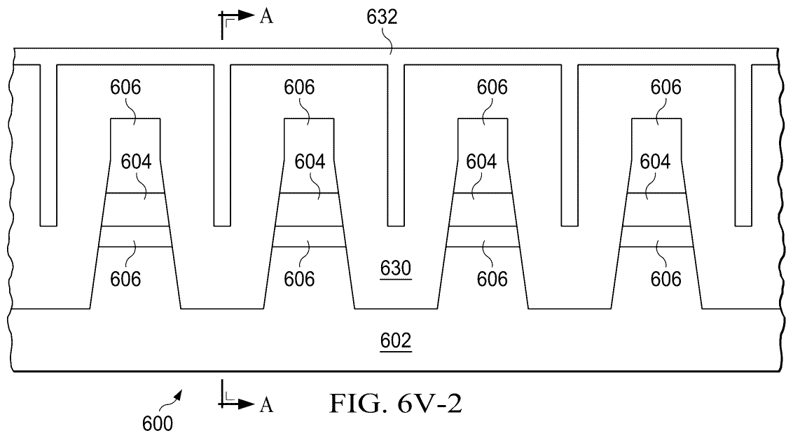

Following formation of the drain drift region 510, a set of fins may be formed in the epitaxial layer 506 (and the drain drift region 510 formed therein) which extend laterally across the structure in the L-direction. The fin hard mask 524 may be used to facilitate formation of the fins. The first electrode portion 521 is then formed, followed by formation of the epitaxial layer 522 and the epitaxial layer 523 for the first section of the super junction. The field relief dielectric layer 525 is then formed, followed by the second electrode portion 526 and the gate spacers 528. On the source side of the LDMOS transistor structure 500, the fin hard mask 524 and the underlying epitaxial layer 506 and epitaxial layer 508 are etched through. An oxide spacer is then formed, followed by selective etching of the epitaxial layer 506 (e.g., which extends laterally underneath a portion of the epitaxial layer 508). A portion of the epitaxial layer 508 (extending to and possibly partially into the drain drift region 510) is then etched selective to the epitaxial layer 506, followed by deposition of an oxide and an anisotropic etch which forms the buried isolation layer 519. The epitaxial layer 506 is then regrown, followed by patterning of the second electrode portion 526. The field relief dielectric layer 525 is then patterned to expose a portion of the structure proximate the drain region 512 where the second section of the super junction will be formed. The drain drift region 510, the epitaxial layer 508 and the epitaxial layer 506 are then etched (potentially down to the buried layer 504), followed by formation of the epitaxial layer 530 and the epitaxial layer 532. Additional details regarding such processing will be described in further detail below with respect to FIGS. 6A-6V.

The silicide layers 534 are formed over the drain region 512, the source region 516 and the body contact region 518 (e.g., exposed silicon regions), followed by deposition of the ILD layer 536 and formation of the contacts 538. The silicide layers 534, which may be referred to as metal silicide layers, may be formed by deposition of a layer of a metal such as titanium or nickel, which is then heated to form a metal silicide in areas where the metal contacts underlying silicon. After the formation of the silicide, the unreacted metal is removed via a wet etch process leaving the silicide layers 534 in the exposed silicon and polysilicon regions. The ILD layer 536 may be an oxide deposited using CVD, and may be doped with phosphorus or phosphorus and boron, where the dopants serve as a getter for mobile ions. The contacts 538 are formed using a pattern and etch process to form contact holes to the underlying layers, the contact holes generally being filled with a metal such as tungsten.

FIG. 5A shows a cross-sectional view taken along one of the fins of the epitaxial layer 506, while FIG. 5B shows a cross-sectional view taken between two of the fins of the epitaxial layer 506. FIG. 5C shows a cross-sectional view along the channel region of the LDMOS transistors structure 500, illustrating the channel composed of a planar or nanosheet portion and multiple fins formed over the planar or nanosheet portion, with the buried isolation layer 519 below the channel region. FIG. 5D shows a cross-sectional view along the first section of the super junction underneath the field relief dielectric layer 525, and FIG. 5E shows a cross-sectional view along the second section of the super junction proximate the drain region 512. As shown in FIGS. 5A and 5B, the buried isolation layer 519 has a lateral length Liso, and a depth Dᵢₛₒ. The channel region, which is in the area between the well region 514, the drain drift region 510, the buried isolation layer 519 and the gate dielectric layer 520, has a thickness t_{Si} (e.g., measured between a top surface of the buried isolation layer 519 and a top of the fins).

Referring now to FIGS. 6A-6V, a method is shown of fabricating an LDMOS device with a buried isolation layer (e.g., buried isolation layer 519) and a super junction with a first section underneath a field relief dielectric layer and a second section proximate a drain region. The method shown in FIGS. 6A-6V, like the method shown in FIGS. 3A-3T, may include the structure shown in FIG. 2G, although only an area of the structure of FIG. 2G (with the nitride layer 214, the oxide layer 212, the hard mask layer 206 and the padding layer 204 removed) between the STI regions 216 is shown for clarity of illustration. It should also be noted that the method shown in FIGS. 6A-6V may start with the structure shown in FIG. 2F, with the nitride layer 214, the oxide layer 212, the hard mask layer 206 and the padding layer 204 removed. The STI regions 216 may still be formed, though later in the processing. As an alternative, the starting structure for FIGS. 6A-6V may include an SOI substrate, where a buried oxide layer replaces the buried epitaxial layer (e.g., a buried silicon germanium layer such as epitaxial layer 508).

FIGS. 6A-1 to 6A-3 shows multiple views of a semiconductor structure 600. FIG. 6A-1 shows a perspective view of the semiconductor structure 600, FIG. 6B shows a section view A-A along an L-direction, similar to the cross-sectional view of FIGS. 5A and 5B, and FIG. 6A-3 shows a section view B-B taken along the W-direction similar to the sectional views of FIGS. 5C, 5D and 5E.

The semiconductor structure 600 of FIG. 6A1-6A3 include an epitaxial layer 602, an epitaxial layer 604, and a heterogenous drain drift region 606 including a doped portion of the epitaxial layer 604. The epitaxial layer 602 is an example of the epitaxial layer 506, and the epitaxial layer 604 is an example of the epitaxial layer 508. The epitaxial layer 602 may be formed of silicon with the first conductivity type (e.g., p-type), while the epitaxial layer 604 is formed of silicon germanium. The drain drift region 606 has the second conductivity type (e.g., n-type), and is formed within the epitaxial layer 602 using one or more ion implant processes, such as using an implant mask and one or more ion implant and anneal processes. The drain drift region 606 may have an average dopant density of about 1×10¹⁵ cm⁻³ to about 1×10¹⁷ cm⁻³, and more specifically, about 5×10¹⁵ cm⁻³ to about 5×10¹⁶ cm⁻³. The drain drift region 606 may have a heavier-doped top portion and a lighter doped bottom portion, to provide desired values of breakdown voltage and specific resistance for an LDMOS device.

As will be discussed in further detail below, a portion of the epitaxial layer 602 will become or provide a channel region for an LDMOS device. A bottom of the channel region will be defined by a buried isolation layer (e.g., similar to the buried isolation layer 519 of the LDMOS transistor structure 500 of FIGS. 5A-5E), with the buried isolation layer providing sufficient separation of the channel region from a remainder of the epitaxial layer 602 in order to reduce short channel effects. The thickness of the channel region may be selected based on whether the LDMOS device that is formed is intended to have a FD channel region during operation or a PD channel region during operation. For a FD channel region, the required thickness of the channel region is less than that for a PD channel region.

FIGS. 6B-1 and 6B-2 respectively show the A-A and B-B cross-sectional views of the semiconductor structure 600 following formation of fins 603 in the epitaxial layer 602 utilizing a fin hard mask 608, where the fins 603 extend across the structure in the L-direction through the drain drift region 606. The A-A cross-sectional view, as shown, is taken along one of the fins 603. The fins 603 may be formed using various types of processing similar to that described above with respect to formation of the fins 303.

As shown in FIG. 6B-2, the portion of the epitaxial layer 602 which remains above the epitaxial layer 604 includes a planar or nanosheet portion 605 and the fins 603 over the planar or nanosheet portion. In some embodiments, an etch stop layer is formed over the epitaxial layer 602, where the etch stop layer may be formed of silicon germanium. The etch stop layer facilitates formation of the planar or nanosheet portion 605 of the epitaxial layer 602 with a uniform thickness, and formation of the fins 603 with a uniform height. Selective etch processing may be used, where the etch rate of silicon (e.g., the material of the epitaxial layer 602) to the material of the etch stop layer (e.g., silicon germanium with a germanium percentage of about 20% to 40%) is greater than 200:1.

The planar or nanosheet portion 605 of the epitaxial layer 602 above the epitaxial layer 604 may have a thickness of about 50 to 200 nm. Each of the fins 603 may have a width of about 100 to 400 nm, and a height of about 100 to 700 nm. The width of the fins 603 may be thicker (e.g., about 1.5 to 2 times thicker) than the planar or nanosheet portion 605 of the epitaxial layer 602, due to the gate electrode being formed on both sides of the fins 603 as discussed in further detail below.

In some examples, the channel doping may be as low as about 5×10¹⁶ to 1×10¹⁹ cm⁻³, depending on the thickness of the channel. For an LDMOS transistor device, the silicon thickness may need to be relatively thick to achieve a desired current and threshold voltage. Thus, the channel doping may need to go up to about pb 4×10¹⁸ to 1×10¹⁹ cm⁻³. This range may work for smaller channel widths without increasing the drain to source current Ids, due to the presence of the planar or nanosheet portion 605 of the epitaxial layer 602 below the fins 603.

FIGS. 6C-1 and 6C-2 respectively show the A-A and B-B cross-sectional views of the semiconductor structure 600 following formation of a gate dielectric layer 610 (e.g., an example of the gate dielectric layer 520 of the LDMOS transistor structure 500 of FIGS. 5A-5C) and a first electrode portion 612 (e.g., an example of the first electrode portion 521 of the LDMOS transistor structure 500 of FIGS. 5A-5E). The gate dielectric layer 610 is deposited over the fins 603 and the planar or nanosheet portion 605 of the epitaxial layer 602, and the first electrode portion 612 is filled over the gate dielectric layer 610. Gate patterning is then performed, by patterning a mask layer over the first electrode portion 612, followed by removal of exposed portions of the first electrode portion 612. The gate dielectric layer 610 may be formed of similar materials and with similar sizing as the gate dielectric layer 308. The first electrode portion 612 may be formed of similar materials as the gate electrode 314.

FIG. 6D-1 shows the A-A cross-sectional view of the semiconductor structure 600 following formation of the first section of the super junction. FIG. 6D-2 shows a C-C cross-sectional view of FIG. 6D-1, which is taken in the W-direction along where the first section of the super junction is formed, similar to the cross-sectional view of FIG. 1C. The first section of the super junction is formed by using selective epitaxial growth processes to grow epitaxial layer 614 (e.g., an example of the epitaxial layer 522 of the LDMOS transistor structure 500 of FIGS. 5A-5E) and epitaxial layer 616 (e.g., an example of the epitaxial layer 523 of the LDMOS transistor structure 500 of FIGS. 5A-5E). The super junction formation includes selective growth of the epitaxial layer 614 over the fins 603 of the drain drift region 606 which are exposed by the patterning of the first electrode portion 612, and formation of epitaxial layer 616 over the epitaxial layer 614. The epitaxial layer 614 is undoped or lightly doped (e.g., having a doping concentration that is less than that of the drain drift region 606 and the epitaxial layer 616), and the epitaxial layer 616 has the first conductivity type (e.g., p-type).

FIGS. 6E-1 and 6E-2 show the A-A and C-C cross-sectional views of the semiconductor structure 600 following formation of a field relief dielectric layer 618 (e.g., an example of field relief dielectric layer 525 of the LDMOS transistor structure 500 of FIGS. 5A and 5D). The field relief dielectric layer 618 may be a low-k dielectric material, and may be formed using similar processing and with similar sizing as that described above with respect to the field relief dielectric layer 310.

FIG. 6F-1 and 6F-2 shows the A-A and C-C cross-sectional views of the semiconductor structure 600 following formation of a second electrode portion 620 (e.g., an example of the second electrode portion 526 of the LDMOS transistor structure 500 of FIGS. 5A-5C). The second electrode portion 620 may be formed of similar materials as the first electrode portion 612. In some examples, the first electrode portion 612 and the second electrode portion 620 have different work functions. The second electrode portion 620 may have a thickness of about 30 to 300 nm.

FIGS. 6G-1 and 6G-2 show the A-A and C-C cross-sectional views of the semiconductor structure 600 following patterning of a mask layer (not shown) over the structure, and etching portions of the second electrode portion 620, the field relief dielectric layer 618 and the first electrode portion 612 to open the source region of the structure, followed by removal of the mask layer. The etch stops on the gate dielectric layer 610.

FIG. 6H shows the A-A cross-sectional view of the semiconductor structure 600 of FIG. 6G following formation of a spacer layer 622. The spacer layer 622 may be formed of a nitride material or a high-k dielectric material, and may have a thickness of about 20 to 200 nm.

FIG. 6I shows the A-A cross-sectional view of the semiconductor structure 600 following etching of the spacer layer 622, with the remaining portion of the spacer layer 622 providing gate spacers (e.g., an example of the gate spacers 528 of the LDMOS transistor structure 500 of FIGS. 5A-5E). The remaining portion of the spacer layer 622 may be referred to as gate spacers 622′. The spacer layer 622 may be etched using an anisotropic etch process that removes the material of the spacer layer 622 from horizontal areas, while leaving the material of the spacer layer 622 on the vertical area (i.e., sidewalls of the second electrode portion 620, the field relief dielectric layer 618 and the first electrode portion 612).

FIG. 6J shows the A-A cross-sectional view of the semiconductor structure 600 following etching of the exposed portion of the fin hard mask 608 and the underlying epitaxial layer 602 and epitaxial layer 604.

FIG. 6K shows the A-A cross-sectional view of the semiconductor structure 600 following formation of a spacer layer 624. The spacer layer 624 may be formed of a nitride or oxide material (different than the material of the spacer layer 622). The spacer layer 624 may have a thickness of about 50 to 200 nm.

FIG. 6L shows the A-A cross-sectional view of the semiconductor structure 600 following etching of the spacer layer 624, with the remaining portion of the spacer layer 624 providing a spacer on a sidewall of the gate spacer 622′ on the source side, as well as the fin hard mask 608, the epitaxial layer 602 and the epitaxial layer 604 exposed by the etching shown in FIG. 6J. This etching may use an anisotropic etch process that removes the spacer layer 624 from horizontal layers, while leaving the material of the spacer layer 624 on the vertical area.

FIG. 6M shows the A-A cross-sectional view of the semiconductor structure 600 following an etching which removes the material of the epitaxial layer 602 selective to the material of the epitaxial layer 604. This etching may have a selectivity of about 100:1 or greater for the material of the epitaxial layer 602 (e.g., silicon) to the material of the epitaxial layer 604 (e.g., silicon germanium). The selective etching of the epitaxial layer 602 results in an undercut region 621 below the bottom surface of the spacer layer 624 and the epitaxial layer 604. To perform a silicon etch that is selective with silicon germanium, the etching process may have a silicon to silicon germanium (Si:SiGe) etch ratio of about 200:1, such that little to no material is removed from epitaxial layer 604 during the etching of the epitaxial layer 602. In some examples, the one or more etching processes may include the use of tetrafluoromethane (CF₄), nitrogen (N₂), oxygen (O₂), and/or difluoromethane (CH₂F₂), among other etchants. The one or more etching processes may utilize an etch pressure from about 150 to 1500 mTorr (20-200 Pa).

FIG. 6N shows the A-A cross-sectional view of the semiconductor structure 600 following an etching which removes the material of the epitaxial layer 604 selective to the material of the epitaxial layer 602 to form a lateral gap 623. The selective etching of the epitaxial layer 604 may use a mixture of hydrofluoric acid (HF), hydrogen peroxide (H₂O₂) and acetic acid (CH₃COOH), which has a selectivity of about 79:1 for the material of the epitaxial layer 604 (e.g., silicon germanium) to the material of the epitaxial layer 602 (e.g., silicon). To perform a selective etching of silicon germanium, in some examples, several etch processes may be used including a selective vapor phase etching with a high partial pressure of HCl at a pressure of about 100 to 400 Tor), or a mixture of CF₄/O2/He plasma at a low pressure between about 5 to 150 mTorr (0.7-20 Pa). In a wet etch process, a mixed solution containing H₂O, HNO₃, CH3COOH and HF may be used.

FIG. 6O shows the A-A cross-sectional view of the semiconductor structure 600 following deposition of an oxide layer 626. The oxide layer 626 may be deposited using ALD to fill in the lateral gap 623, followed by a flowable oxide deposition process to fill in the remainder of the structure as shown.

FIG. 6P shows the A-A cross-sectional view of the semiconductor structure 600 following etching of the oxide layer 626. The oxide layer 626 may be etched using an anisotropic etch process which removes the material of the oxide layer 626 from horizontal areas, while leaving the material of the oxide layer 626 on the vertical area (e.g., filling in the lateral gap 623 and the undercut region 621). The remaining portion of the oxide layer 626 provides a buried isolation spacer (e.g., an example of the buried isolation layer 519 of the LDMOS transistor structure 500 of FIGS. 5A-5C).

FIG. 6Q shows the A-A cross-sectional view of the semiconductor structure 600 following a selective growth of epitaxial layer 628 over the epitaxial layer 602. In some examples, there is a seam or void 627 between the epitaxial layer 602 and the epitaxial layer 638. The seam or void 627, however, is in the source area which is the lower voltage side for an LDMOS device. In other examples, there is no seam or void 627 as the epitaxial layer 628 may be formed by deposition of amorphous silicon followed by etch and recess, and regrowing silicon crystal to avoid the seam or void 627. The epitaxial growth of the epitaxial layer 628 may utilize an MBE process, a CVD process, an MOCVD process, other suitable epitaxial growth process, or combinations thereof.

FIGS. 6R-1 shows the A-A cross-sectional view of the semiconductor structure 600 following gate patterning. FIG. 6R-2 is a cross-sectional view along line D-D of FIG. 6R-1, showing a region where a second section of the super junction will be formed. The gate patterning includes patterning a mask layer (not shown) over the structure, followed by removal of portions of the second electrode portion 620 exposed by the mask layer, revealing part of the field relief dielectric layer 618 formed over the drain drift region 606 proximate where the drain region of the LDMOS device will be formed. The mask layer is then removed.

FIGS. 6S-1 and 6S-2 respectively show the A-A and D-D cross-sectional views of the semiconductor structure 600 following patterning of the field relief dielectric layer 618. This patterning includes patterning a mask layer (not shown) over the structure, followed by removal of portions of the field relief dielectric layer 618 exposed by the mask layer, revealing part of the epitaxial layer 616 and fin hard mask 608 where the second section of the super junction will be formed. The mask layer is then removed.

FIGS. 6T-1 and 6T-2 respectively show the A-A and D-D cross-sectional views of the semiconductor structure 600 following etching of portions of the epitaxial layer 616, the epitaxial layer 614, the drain drift region 606, the epitaxial layer 604 and the epitaxial layer 602 which are not covered by the fin hard mask 608. This etching extends partway through the epitaxial layer 602 which is below the drain drift region 606 (potentially down to a buried layer such as the buried layer 504 of the LDMOS transistor structure 500 of FIGS. 5A-5E).

FIGS. 6U-1 and 6U-2 respectively show the A-A and D-D cross-sectional views of the semiconductor structure 600 following removal of exposed portions of the fin hard mask 608. The fin hard mask 608 may be removed using a suitable etch process.

FIGS. 6V-1 and 6V-2 respectively show the A-A and D-D cross-sectional views of the semiconductor structure 600 following formation of the second section of the super junction. This includes forming an epitaxial layer 630 (e.g., an example of the epitaxial layer 530 of the LDMOS transistor structure 500 of FIGS. 5A-5E) over the fins 603, and forming an epitaxial layer 632 (e.g., an example of the epitaxial layer 532 of the LDMOS transistor structure 500 of FIGS. 5A-5E) over the epitaxial layer 630. The formation of the second section of the super junction includes selective growth of the epitaxial layer 630, and formation of epitaxial layer 632 over the epitaxial layer 630. The epitaxial layer 630 is undoped or lightly doped (e.g., having a doping concentration that is less than that of the drain drift region 606 and the epitaxial layer 632), and the epitaxial layer 632 has the first conductivity type (e.g., p-type).

The semiconductor structure 600 of FIGS. 6V-1 and 6V-2 may be subject to further processing to form a drain region, a well region, a source region, a body contact region, silicide layers, an ILD layer and contacts (e.g., the drain region 512, the well region 514, the source region 516, the body contact region 518, the silicide layers 534, the ILD layer 536 and the contacts 538 of the LDMOS transistor structure 500 of FIGS. 5A-5E).

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer comprising a planar portion and two or more fins disposed over the planar portion;
a source region disposed in the semiconductor layer;
a drain drift region disposed in the semiconductor layer;
a drain region disposed in the drain drift region;
the two or more fins of the semiconductor layer extending from the source region through the drain drift region to the drain region;
a first epitaxial layer disposed over a portion of the two or more fins of the semiconductor layer in the drain drift region;
a second epitaxial layer disposed over the first epitaxial layer, the drain drift region having a first doping type and the second epitaxial layer having a second doping type;
a gate electrode; and
a field relief insulating layer disposed between a portion of the gate electrode and a portion of the second epitaxial layer.

2. The semiconductor device of claim 1, wherein the first epitaxial layer is undoped.

3. The semiconductor device of claim 1, wherein the first epitaxial layer comprises a doping concentration of the first doping type that is less than a doping concentration of the drain drift region.

4. The semiconductor device of claim 1, wherein the second epitaxial layer comprises vertical sections disposed in the first epitaxial layer between the two or more fins in the drain drift region.

5. The semiconductor device of claim 1, wherein the one or more fins of the semiconductor layer have a first height in a first portion of the drain drift region below the field relief insulating layer and have a second height in a second portion of the drain drift region between the field relief insulating layer and the drain region.

6. The semiconductor device of claim 5, wherein the second epitaxial layer comprises vertical sections disposed between adjacent ones of the two or more fins in the drain drift region, the vertical sections having a first height in the first portion of the drain drift region below the field relief insulating layer and a second height in the second portion of the drain drift region between the field relief insulating layer and the drain region.

7. The semiconductor device of claim 1, further comprising an isolation layer buried in the semiconductor layer below a portion of the gate electrode and extending from the source region to the drain drift region.

8. The semiconductor device of claim 7, wherein the isolation layer comprises a first portion that extends laterally between the source region and the drain drift region and a second portion that extends vertically into the semiconductor layer away from the gate electrode.

9. The semiconductor device of claim 1, wherein the gate electrode comprises a first portion and a second portion, the field relief insulating layer being disposed between the first portion and the second portion of the gate electrode, the first portion of the gate electrode being disposed over a portion of the two or more fins of the semiconductor layer between the source region and the drain drift region, the field relief insulating layer being disposed over a top surface of the first portion of the gate electrode and a portion of the drain drift region, the second portion of the gate electrode extending over at least a portion of the top surface of the field relief insulating layer.

10. The semiconductor device of claim 1, wherein the semiconductor device comprises a laterally-diffused metal-oxide semiconductor (LDMOS) transistor.

11. A method of fabricating a semiconductor device, comprising:
forming two or more fins in at least a portion of a semiconductor layer;
forming a source region in the semiconductor layer;
forming a drain drift region in the semiconductor layer;
forming a drain region in the drain drift region, the two or more fins of the semiconductor layer extending from the source region through the drain drift region to the drain region;
forming a first epitaxial layer over a portion of the two or more fins of the semiconductor layer in the drain drift region;
forming a second epitaxial layer over the first epitaxial layer, the drain drift region having a first doping type and the second epitaxial layer having a second doping type;
forming a gate electrode; and
forming a field relief insulating layer disposed between a portion of the gate electrode and a portion of the second epitaxial layer.

12. The method of claim 11, further comprising forming an isolation layer buried in the semiconductor layer below a portion of the gate electrode and extending from the source region to the drain drift region.

13. The method of claim 11, wherein forming the gate electrode comprises:
forming a gate dielectric layer over a portion of the two or more fins of the semiconductor layer;
forming the gate electrode over the gate dielectric layer;
patterning a mask layer over the gate electrode; and
removing portions of the gate electrode and the gate dielectric layer exposed by the mask layer.

14. The method of claim 11, wherein forming the gate electrode comprises:
forming a first portion of the gate electrode over a portion of the two or more fins of the semiconductor layer extending from the source region through a portion of the drain drift region;
forming the first epitaxial layer over a portion of the two or more fins of the semiconductor layer in the drain drift region extending from the first portion of the gate electrode to the drain region;
forming the second epitaxial layer over the first epitaxial layer;
forming the field relief insulating layer over the first portion of the gate electrode and the second epitaxial layer; and
forming a second portion of the gate electrode over a portion of the field relief insulating layer.

15. The method of claim 11, wherein forming the gate electrode comprises:
forming the field relief insulating layer over a portion of the two or more fins of the semiconductor layer in the drain drift region; and
forming the gate electrode over a portion of the two or more fins of the semiconductor layer extending from the source region and over a portion of the field relief insulating layer.

16. The method of claim 11, wherein forming the first epitaxial layer comprises:
patterning a mask layer over the field relief insulating layer;
removing portions of the field relief insulating layer exposed by the mask layer; and
forming the first epitaxial layer over a portion of the two or more fins of the semiconductor layer in the drain drift region extending from the field relief insulating layer to the drain region.

17. A method of fabricating a semiconductor device, comprising:
forming two or more fins in at least a portion of a semiconductor layer;
forming a source region in the semiconductor layer;
forming a drain drift region in the semiconductor layer;
forming a drain region in the drain drift region, the two or more fins of the semiconductor layer extending from the source region through the drain drift region to the drain region;
forming a gate electrode having a first portion and a second portion;
forming a field relief insulating layer disposed between the first and second portions of the gate electrode;
forming a first epitaxial layer over first and second portions of the two or more fins of the semiconductor layer in the drain drift region, the first portion of the two or more fins of the semiconductor layer below the field relief insulating layer having a first height and the second portion of the two or more fins of the semiconductor layer extending from the field relief insulating layer to the drain region having a second height; and
forming a second epitaxial layer over the first epitaxial layer, the drain drift region having a first doping type and the second epitaxial layer having a second doping type.

18. The method of claim 17, wherein the second height is greater than the first height.

19. The method of claim 17, wherein the second height extends in the semiconductor layer below the drain drift region.

20. The method of claim 17, wherein the second epitaxial layer comprises vertical section disposed in the first epitaxial layer between the two or more fins in the drain drift region.
